(19) United States
(12) Patent Application Publication
(10) Pub. No.: US 2026/0113971 A1
(43) Pub. Date: Apr. 23, 2026

(54) SEMICONDUCTOR DEVICE

(71) Applicant: SAMSUNG ELECTRONICS CO., LTD., Suwon-si (KR)

(72) Inventor: Soo Yeon JEONG, Suwon-si (KR)

(73) Assignee: SAMSUNG ELECTRONICS CO., LTD., Suwon-si (KR)

(21) Appl. No.: 19/212,067

(22) Filed: May 19, 2025

(30) Foreign Application Priority Data
Oct. 22, 2024 (KR) 10-2024-0144880
Dec. 10, 2024 (KR) 10-2024-0182405

(51) Int. Cl. H10D 30/00; H10D 30/01

(52) U.S. Cl. CPC H10D 30/508; H10D 30/0197; H10D 30/509

(57) ABSTRACT

A semiconductor device may include: a lower insulating pattern including a first surface, a second surface opposite to the first surface in a first direction, and a sidewall connecting the first surface to the second surface; a first sheet pattern in contact with the first surface of the lower insulating pattern; a second sheet pattern on the first sheet pattern, spaced apart from the first sheet pattern in the first direction; a gate structure including an inner gate structure, the inner gate structure being between the first sheet pattern and the second sheet pattern, extending in a second direction, and including a gate electrode and a gate insulating film; a source/drain pattern connected to the first sheet pattern and the second sheet pattern; and a bottom insulating spacer below the source/drain pattern in the first direction, and overlapped with the source/drain pattern in the first direction.

### CROSS-REFERENCE TO RELATED APPLICATION

This application claims priority from Korean Patent Application No. 10-2024-0144880, filed on Oct. 22, 2024, and Korean Patent Application No. 10-2024-0182405, filed on Dec. 10, 2024, in the Korean Intellectual Property Office, and all the benefits accruing therefrom under 35 U.S.C. 119, the disclosures of which are herein incorporated by reference in their entireties.

### BACKGROUND

### 1. Field

The disclosure relates to a semiconductor device, and more particularly, to a semiconductor device that includes a Multi-Bridge Channel Field Effect Transistor (MBCFET™).

### 2. Brief Description of Related Art

As one of scaling techniques for increasing a density of a semiconductor device, a multi-gate transistor for forming a multi-channel active pattern (or silicon body) of a fin or nanowire shape on a substrate and forming a gate on a surface of the multi-channel active pattern has been suggested.

Since this multi-gate transistor uses a three-dimensional channel, it is easy to scale the multi-gate transistor. Also, even though a gate length of the multi-gate transistor is not increased, a current control capability may be improved. In addition, a short channel effect (SCE) in which a potential of a channel region is affected by a drain voltage may be suppressed effectively.

### SUMMARY

According to an aspect of the disclosure, a semiconductor device capable of improving device performance and reliability may be provided.

According to an aspect of the disclosure, a semiconductor device may include: a lower insulating pattern including a first surface, a second surface opposite to the first surface in a first direction, and a sidewall connecting the first surface to the second surface; a first sheet pattern in contact with the first surface of the lower insulating pattern; a second sheet pattern on the first sheet pattern, spaced apart from the first sheet pattern in the first direction; a gate structure including an inner gate structure, the inner gate structure being between the first sheet pattern and the second sheet pattern, and extending in a second direction that crosses the first direction, and the inner gate structure including a gate electrode and a gate insulating film; a source/drain pattern connected to the first sheet pattern and the second sheet pattern; and a bottom insulating spacer below the source/drain pattern in the first direction, and overlapped with the source/drain pattern in the first direction, wherein the bottom insulating spacer includes a first insulating material, and the lower insulating pattern includes a second insulating material that is different from the first insulating material, and wherein a thickness of the inner gate structure in the first direction is smaller than a thickness of the lower insulating pattern in the first direction.

According to an aspect of the disclosure, a semiconductor device may include: a lower insulating pattern including: an upper plate portion, a lower plate portion spaced apart from the upper plate portion in a first direction, and a sidewall portion connecting the upper plate portion to the lower plate portion; a first sheet pattern on the lower insulating pattern, the first sheet pattern being in contact with the upper plate portion of the lower insulating pattern; a second sheet pattern on the first sheet pattern, spaced apart from the first sheet pattern in the first direction; a gate structure including an inner gate structure between the first sheet pattern and the second sheet pattern, the inner gate structure extending in a second direction crossing the first direction, and the inner gate structure including a gate electrode and a gate insulating film; an inner spacer between the first sheet pattern and the second sheet pattern; a source/drain pattern connected to the first sheet pattern and the second sheet pattern; and a bottom insulating spacer below the source/drain pattern in the first direction, the bottom insulating spacer overlapped with the source/drain pattern in the first direction, and in contact with the lower insulating pattern.

According to an aspect of the disclosure, a semiconductor device may include: a lower insulating pattern including an air gap, a first surface, and a second surface opposite to the first surface in a first direction; a first sheet pattern in contact with the first surface of the lower insulating pattern; a second sheet pattern on the first sheet pattern, spaced apart from the first sheet pattern in the first direction; a gate structure including an inner gate structure, the inner gate structure being between the first sheet pattern and the second sheet pattern, and extending in a second direction that crosses the first direction, and the inner gate structure including a gate electrode and a gate insulating film; an inner spacer between the first sheet pattern and the second sheet pattern; a first source/drain pattern connected to the first sheet pattern and the second sheet pattern; a second source/drain pattern connected to the first sheet pattern and the second sheet pattern, and spaced apart from the first source/drain pattern in a third direction that crosses the first direction and the second direction; a frontside wiring line on the first surface of the lower insulating pattern; a backside wiring line on the second surface of the lower insulating pattern; a first bottom insulating spacer below the first source/drain pattern in the first direction, and overlapped with the first source/drain pattern in the first direction; a backside source/drain contact passing through the first bottom insulating spacer and connecting the first source/drain pattern to the backside wiring line; and a frontside source/drain contact connecting the second source/drain pattern to the frontside wiring line.

However, aspects and effects of embodiments of the disclosure are not restricted to those set forth herein. The above and other aspects and effects of embodiments of the disclosure will become more apparent to one of ordinary skill in the art to which the disclosure pertains by referencing the detailed description of the disclosure given below.

### BRIEF DESCRIPTION OF DRAWINGS

The above and other aspects and features of the disclosure will become more apparent by describing in detail non-limiting example embodiments thereof with reference to the attached drawings, in which:

FIG. 1 is an example plan view illustrating a semiconductor device according to some embodiments.

FIG. 2 is a cross-sectional view taken along a line A-A of FIG. 1.

FIG. 3 is a cross-sectional view taken along a line B-B of FIG. 1.

FIG. 4 is a view illustrating a shape of a lower insulating pattern of FIG. 2.

FIG. 5 is an enlarged view illustrating a portion P of FIG. 2.

FIGS. 6 and 7 are views illustrating a semiconductor device according to some embodiments.

FIGS. 8 and 9 are views illustrating a semiconductor device according to some embodiments, respectively.

FIG. 10 is a view illustrating a semiconductor device according to some embodiments.

FIG. 11 is a view illustrating a semiconductor device according to some embodiments.

FIGS. 12 to 14 are views illustrating a semiconductor device according to some embodiments.

FIGS. 15 and 16 are views illustrating a semiconductor device according to some embodiments.

FIG. 17 is a view illustrating a semiconductor device according to some embodiments.

FIGS. 18 to 36 are views illustrating intermediate steps to describe a method for fabricating a semiconductor memory device according to some embodiments.

### DETAILED DESCRIPTION

It will be understood that, although the terms “first,” “second,” “third,” and so on may be used herein to describe various elements, components, regions, layers and/or sections, these elements, components, regions, layers, and/or sections should not be limited by these terms. These terms are used to distinguish one element, component, region, layer, or section from another element, component, region, layer, or section. Thus, a first element, component, region, layer, or section described below could be termed a second element, component, region, layer, or section, without departing from the spirit and scope of the disclosure.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

A semiconductor device according to some embodiments may include a tunneling transistor (e.g., a tunneling Field Effect Transistor (FET)), a three-dimensional (3D) transistor, or a two-dimensional (2D) material based FET and a heterostructure thereof. Also, the semiconductor device according to some embodiments may include a bipolar junction transistor, a laterally diffused metal oxide semiconductor (LDMOS) transistor, and the like.

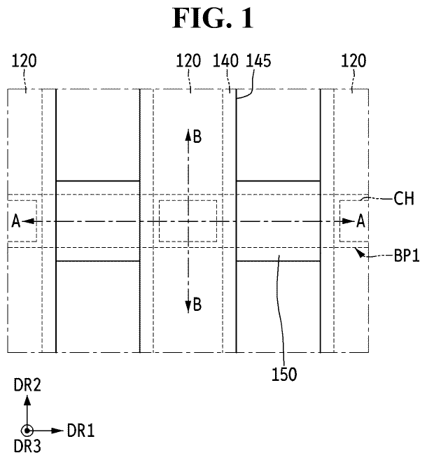

The semiconductor device according to some embodiments will be described with reference to FIGS. 1 to 5.

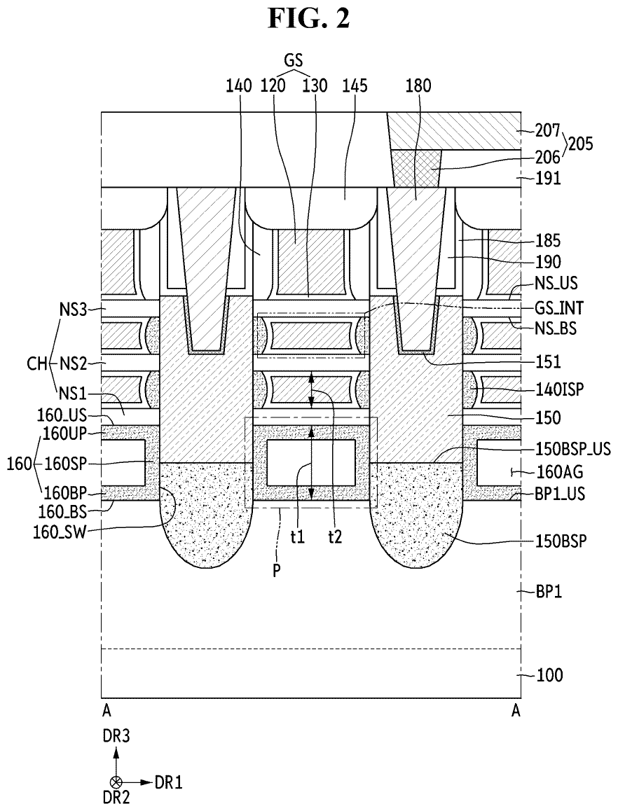

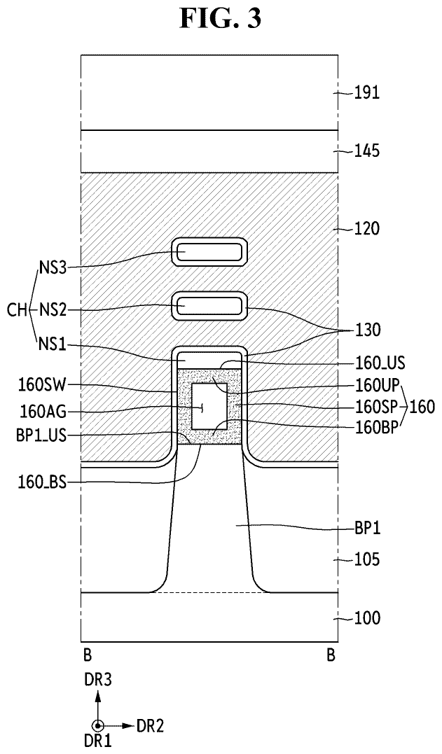

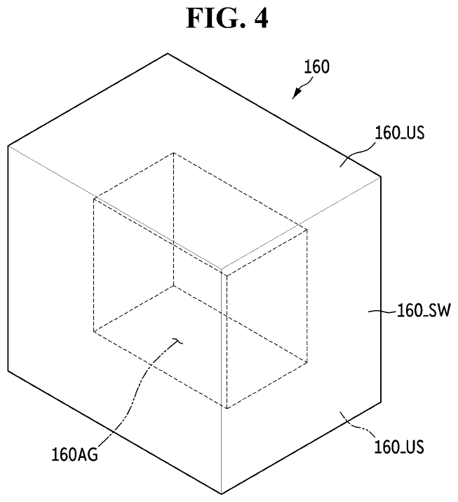

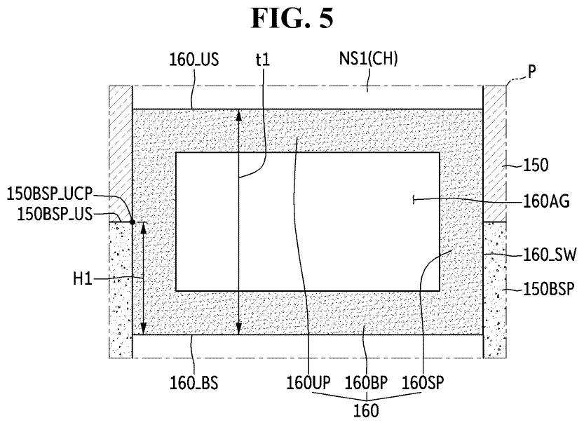

FIG. 1 is an example plan view illustrating a semiconductor device according to some embodiments. FIG. 2 is a cross-sectional view taken along a line A-A of FIG. 1. FIG. 3 is a cross-sectional view taken along a line B-B of FIG. 1. FIG. 4 is a view illustrating a shape of a lower insulating pattern of FIG. 2. FIG. 5 is an enlarged view illustrating a portion P of FIG. 2.

For reference, components of a semiconductor device are shown in FIG. 1, except, for example, a gate insulating film 130, a source/drain etching stop film 185, interlayer insulating layers (e.g., a first interlayer insulating layer 190 and a second interlayer insulating layer 191), and a frontside wiring structure 205 (see FIG. 2).

Referring to FIGS. 1 to 5, the semiconductor device according to some embodiments may include a first lower pattern BP1, a channel pattern NS, a gate electrode 120, an inner spacer 140ISP, a bottom insulating spacer 150BSP, a lower insulating pattern 160, and a source/drain pattern 150.

A first substrate 100 may be provided, and may be a bulk silicon or a silicon-on-insulator (SOI). Alternatively, the first substrate 100 may be a silicon substrate, or may include another material such as, for example, silicon germanium, silicon germanium on insulator (SGOI), indium antimonide, lead telluride, indium arsenide, indium phosphide, gallium arsenide, or gallium antimonide, but is not limited thereto.

The first lower pattern BP1 may protrude from the first substrate 100 in a third direction DR3. The first lower pattern BP1 may be elongated in a first direction DR1. The first lower pattern BP1 may include a long side extending in the first direction DR1 and a short side extending in a second direction DR2. For example, the first direction DR1 and the second direction DR2 may be orthogonal to the third direction DR3. The first direction DR1 may be orthogonal to the second direction DR2.

The first lower pattern BP1 may be formed by etching a portion of the first substrate 100, or may include an epitaxial layer grown from the first substrate 100. The first lower pattern BP1 may include silicon or germanium, which is an elemental semiconductor material. In addition, the first lower pattern BP1 may include a compound semiconductor, and may include, for example, a group IV-IV compound semiconductor or a group III-V compound semiconductor.

The group IV-IV compound semiconductor may be a binary compound or ternary compound, which includes at least two from among carbon (C), silicon (Si), germanium (Ge), and tin (Sn), or a compound including at least two from among carbon (C), silicon (Si), germanium (Ge), and tin (Sn), which are doped with a group IV element.

The group III-V compound semiconductor may be, for example, one from among a binary compound, a ternary compound, and a quaternary compound, which is formed by combination of at least one from among aluminum (Al), gallium (Ga), and indium (In), which is a group III element, and one from among phosphorus (P), arsenic (As), and antimony (Sb), which are group V elements.

A field insulating layer 105 may be disposed on the first substrate 100. The field insulating layer 105 may be disposed on a sidewall of the first lower pattern BP1. The field insulating layer 105 may not be disposed on an upper surface of a first lower pattern BP1_US.

As an example, the field insulating layer 105 may entirely cover the sidewall of the first lower pattern BP1. According to an embodiment, the field insulating layer 105 may cover a portion of the sidewall of the first lower pattern BP1. In this case, a portion of the first lower pattern BP1 may protrude more in the third direction DR3 than an upper surface of the field insulating layer 105.

The upper surface of the field insulating layer 105 may have a concave shape, but is not limited thereto. The field insulating layer 105 may include, for example, silicon oxide, silicon nitride, silicon oxynitride, or a combination thereof. Although the field insulating layer 105 is shown as a single layer, it is only for convenience of description, and embodiments of the disclosure are not limited thereto.

The lower insulating pattern 160 may be disposed on the first lower pattern BP1. The lower insulating pattern 160 may be disposed on the upper surface BP1_US of the first lower pattern BP1. The lower insulating pattern 160 may be in contact with the upper surface BP1_US of the first lower pattern BP1.

The lower insulating pattern 160 includes a first surface 160_US and a second surface 160_BS, which may be opposite to each other in the third direction DR3. The second surface 160_BS of the lower insulating pattern 160 may face the first lower pattern BP1. The second surface 160_BS of the lower insulating pattern 160 may be in contact with the upper surface BP1_US of the first lower pattern BP1. For example, in FIG. 2, the upper surface BP1_US of the first lower pattern BP1 may be a contact surface that is in contact with the lower insulating pattern 160.

The lower insulating pattern 160 may include sidewalls 160_SW opposite to each other in the first direction DR1 and the second direction DR2. The sidewalls of the lower insulating pattern 160_SW may connect the first surface 160_US of the lower insulating pattern 160 to the second surface 160_BS of the lower insulating pattern 160.

The second surface 160_BS of the lower insulating pattern 160 may be coplanar with the upper surface of the field insulating layer 105 based on a bottom surface of a fin trench that defines a sidewall of the first lower pattern BP1. The field insulating layer 105 may not cover the sidewall 160_SW of the lower insulating pattern 160. According to an embodiment, the second surface 160_BS of the lower insulating pattern 160 may be higher than the upper surface of the field insulating layer 105 based on the bottom surface of the fin trench that defines the sidewall of the first lower pattern BP1.

The lower insulating pattern 160 may not protrude more in the second direction DR2 than the first lower pattern BP1. In a cross-sectional view as shown in FIG. 3, the sidewall 160_SW of the lower insulating pattern 160 may not protrude more in the second direction DR2 than the sidewall of the first lower pattern BP1. The lower insulating pattern 160 may not extend along the upper surface of the field insulating layer 105. That is, the lower insulating pattern 160 may not cover the upper surface of the field insulating layer 105.

In the semiconductor device according to some embodiments, the lower insulating pattern 160 may have a box shape. For example, the lower insulating pattern 160 may include an upper plate portion 160UP and a lower plate portion 160BP, which may be spaced apart from each other in the third direction DR3. The lower insulating pattern 160 may include a sidewall portion 160SP connecting the upper plate portion 160UP with the lower plate portion 160BP. The lower insulating pattern 160 may include an air gap 160AG surrounded by the upper plate portion 160UP, the lower plate portion 160BP, and the sidewall portion 160SP.

The upper plate portion 160UP may include the first surface 160_US. The lower plate portion 160BP may include the second surface 160_BS.

The lower insulating pattern 160 may include a first insulating material. The first insulating material may include, for example, a silicon nitride-based insulating material. In this case, the silicon nitride-based insulating material may be a material, in which at least one from among carbon (C) and oxygen (O) is included in silicon nitride, as well as silicon nitride. For example, the first insulating material may include one from among silicon oxynitride, silicon oxycarbonitride, and silicon carbonitride. For example, the first insulating material may be silicon oxycarbonitride. The lower insulating pattern 160 may include silicon oxycarbonitride.

The channel pattern CH may be disposed on the lower insulating pattern 160. The channel pattern CH may be disposed on the first surface 160_US of the lower insulating pattern 160. The channel pattern CH may overlap the lower insulating pattern 160 in the third direction DR3.

The channel pattern CH may include a plurality of sheet patterns spaced apart from one another in the third direction DR3. The plurality of sheet patterns of the channel pattern CH may include a first sheet pattern NS1, a second sheet pattern NS2, and a third sheet pattern NS3. The first sheet pattern NS1, the second sheet pattern NS2, and the third sheet pattern NS3 may be spaced apart from one another in the third direction DR3. Although the channel pattern CH is shown as including three sheet patterns, embodiments of the disclosure are not limited thereto.

The second sheet pattern NS2 may be disposed between the first sheet pattern NS1 and the third sheet pattern NS3. The first sheet pattern NS1 may be disposed between the second sheet pattern NS2 and the lower insulating pattern 160.

The first sheet pattern NS1 may be in contact with the lower insulating pattern 160. The first sheet pattern NS1 may be in contact with the first surface 160_US of the lower insulating pattern 160. In the semiconductor device according to some embodiments, the first sheet pattern NS1 may be in contact with the upper plate portion 160UP of the lower insulating pattern 160.

Each of the first sheet pattern NS1, the second sheet pattern NS2, and the third sheet pattern NS3 may include an upper surface NS_US and a lower surface NS_BS, which may be opposite to each other in the third direction DR3. The lower surfaces NS_BS of the first to third sheet patterns NS1, NS2, and NS3 may face towards the lower insulating pattern 160. The bottom surface NS_BS of the first sheet pattern NS1 may be in contact with the lower insulating pattern 160. The upper surface NS_US of the third sheet pattern NS3 may be an upper surface of the channel pattern CH.

The first sheet pattern NS1, the second sheet pattern NS2, and the third sheet pattern NS3 may include one from among silicon and germanium, which is an elemental semiconductor material, a group IV-IV compound semiconductor, and a group III-V compound semiconductor. The first sheet pattern NS1, the second sheet pattern NS2, and the third sheet pattern NS3 may include the same material as a material of the first lower pattern BP1, or may include a material different from a material of the first lower pattern BP1.

In the semiconductor device according to some embodiments, the first lower pattern BP1 may be a silicon lower pattern containing silicon. Each of the first sheet pattern NS1, the second sheet pattern NS2, and the third sheet pattern NS3 may be a silicon sheet pattern containing silicon.

A plurality of gate structures GS may be disposed on the first substrate 100. Each of the gate structures GS may extend in the second direction DR2. The gate structures GS may be disposed to be spaced apart from each other in the first direction DR1. For example, the gate structures GS may be disposed on both sides of the source/drain pattern 150 in the first direction DR1.

The gate structure GS may be disposed on the first lower pattern BP1. The gate structure GS may cross the first lower pattern BP1. The gate structure GS may include, for example, a gate electrode 120 and a gate insulating film 130.

The gate structures GS may surround each of the second sheet pattern NS2 and the third sheet pattern NS3. Since the first sheet pattern NS1 and the lower insulating pattern 160 may be in contact with each other, the gate structures GS may not surround the circumference of the first sheet pattern NS1 in the cross-sectional view as shown in FIG. 3.

The gate structure GS may include an inner gate structure GS_INT disposed between the first sheet pattern NS1 and the second sheet pattern NS2, which may be adjacent to each other in the third direction DR3, and between the second sheet pattern NS2 and the third sheet pattern NS3. The inner gate structure GS_INT may not be disposed between the first sheet pattern NS1 and the lower insulating pattern 160, which may be adjacent to each other in the third direction DR3. The inner gate structure GS_INT may include the gate electrode 120 and the gate insulating film 130.

The number of the inner gate structures GS_INT may be proportional to the number of the sheet patterns (e.g., the first sheet pattern NS1, the second sheet pattern NS2, and the third sheet pattern NS3) included in the channel pattern CH. Since the first sheet pattern NS1 and the lower insulating pattern 160 may be in contact with each other, the number of the inner gate structures GS_INT may be less than the number of the sheet patterns included in the channel pattern CH by as much as one.

A thickness t1 of the lower insulating pattern 160 in the third direction DR3 may be different from a thickness t2 of the inner gate structure GS_INT in the third direction DR3. For example, the thickness t1 of the lower insulating pattern 160 may be greater than the thickness t2 of the inner gate structure GS_INT.

The gate electrode 120 may be disposed on the first lower pattern BP1. The gate electrode 120 may cross the first lower pattern BP1.

The gate electrode 120 may be disposed on the lower insulating pattern 160. The gate electrode 120 may overlap the lower insulating pattern 160 in the third direction DR3. The gate electrodes 120 may surround the second sheet pattern NS2 and the third sheet pattern NS3.

The gate electrodes 120 may include at least one from among metal, a metal alloy, a conductive metal nitride, a metal silicide, a doped semiconductor material, a conductive metal oxide, and a conductive metal oxynitride. The gate electrode 120 may include, but is not limited to, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. The conductive metal oxide and the conductive metal oxynitride may include, but are not limited to, oxidized forms of the materials described above.

The gate electrodes 120 may be disposed on opposite sides of the source/drain pattern 150, which will be described later. The gate structures GS may be disposed on opposite sides of the source/drain pattern 150 in the first direction D1.

For example, the gate electrodes 120 disposed on both sides of the source/drain pattern 150 may be normal gate electrodes used as gates of transistors. In another example, the gate electrode 120 disposed on one side of the source/drain pattern 150 may be used as a gate of the transistor, but the gate electrode 120 disposed on the other side of the source/drain pattern 150 may be a dummy gate electrode.

The gate insulating film 130 may extend along the upper surface of the field insulating layer 105. The gate insulating film 130 may extend along the sidewall 160_SW of the lower insulating pattern 160 and the upper surface NS_US of the first sheet pattern NS1. The gate insulating film 130 may be in contact with the sidewall 160_SW of the lower insulating pattern 160. The gate insulating film 130 may be in contact with the upper surface NS_US of the first sheet pattern NS1. The gate insulating film 130 may not be in contact with the bottom surface NS_BS of the first sheet pattern NS1.

The gate insulating film 130 may be surround the second sheet pattern NS2 and the third sheet pattern NS3. The gate insulating film 130 may be disposed along the circumference of the second sheet pattern NS2 and the circumference of the third sheet pattern NS3. The gate electrode 120 may be disposed on the gate insulating film 130. The gate insulating film 130 may be disposed between the gate electrode 120 and the sheet patterns (e.g., the first sheet pattern NS1, the second sheet pattern NS2, and the third sheet pattern NS3).

The gate insulating film 130 may include silicon oxide, silicon-germanium oxide, germanium oxide, silicon oxynitride, silicon nitride, or a high dielectric constant material having a dielectric constant greater than a dielectric constant of silicon oxide. For example, the high dielectric constant material may include at least one from among boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The gate insulating film 130 is shown as a single film, but this is for convenience of description, and is not limited thereto. The gate insulating film 130 may include a plurality of films. The gate insulating film 130 may include an interfacial layer disposed between the gate electrode 120 and the channel pattern CH, and a high dielectric constant insulating film.

The semiconductor device according to some embodiments may include a negative capacitance (NC) FET based on a negative capacitor. For example, the gate insulating film 130 may include a ferroelectric material film having ferroelectric characteristics and a paraelectric material film having paraelectric characteristics.

The ferroelectric material film may have a negative capacitance, and the paraelectric material film may have a positive capacitance. For example, when two or more capacitors are connected in series, and the capacitance of each capacitor has a positive value, the total capacitance may be lower than the capacitance of each individual capacitor. On the other hand, when at least one of capacitances of two or more capacitors connected in series has a negative value, the total capacitance may have a positive value and may be greater than an absolute value of each individual capacitance.

When a ferroelectric material film having a negative capacitance and a paraelectric material film having a positive capacitance are connected in series, the total capacitance value of the ferroelectric material film and the paraelectric material film, which are connected in series, may be increased. Based on the total capacitance value that is increased, a transistor having a ferroelectric material film may have a subthreshold swing (SS) less than 60 mV/decade at a room temperature.

The ferroelectric material film may have ferroelectric characteristics. The ferroelectric material film may include at least one from among, for example, hafnium oxide, hafnium zirconium oxide, barium strontium titanium oxide, barium titanium oxide, and lead zirconium titanium oxide. In this case, for example, the hafnium zirconium oxide may be a material doped with zirconium (Zr) in hafnium oxide. In another example, the hafnium zirconium oxide may be a compound of hafnium (Hf) and zirconium (Zr), and oxygen (O).

The ferroelectric material film may further include a doped dopant. For example, the dopant may include at least one from among aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). A type of the dopant included in the ferroelectric material film may be varied depending on the ferroelectric material of the ferroelectric material film.

When the ferroelectric material film includes hafnium oxide, the dopant included in the ferroelectric material film may include at least one from among gadolinium (Gd), silicon (Si), zirconium (Zr), aluminum (Al), and yttrium (Y).

When the dopant is aluminum (Al), the ferroelectric material film may include aluminum of 3 at % to 8 at % (atomic %). In this case, a ratio of the dopant may be a ratio of aluminum to a sum of hafnium and aluminum.

When the dopant is silicon (Si), the ferroelectric material film may include silicon of 2 at % to 10 at %. When the dopant is yttrium (Y), the ferroelectric material film may include yttrium of 2 at % to 10 at %. When the dopant is gadolinium (Gd), the ferroelectric material film may include gadolinium of 1 at % to 7 at %. When the dopant is zirconium (Zr), the ferroelectric material film may include zirconium of 50 at % to 80 at %.

The paraelectric material film may have paraelectric characteristics. The paraelectric material film may include at least one from among, for example, silicon oxide and metal oxide having a high dielectric constant. The metal oxide included in the paraelectric material film may include, but is not limited to, at least one from among hafnium oxide, zirconium oxide, and aluminum oxide.

The ferroelectric material film and the paraelectric material film may contain the same material. Although the ferroelectric material film has ferroelectric characteristics, the paraelectric material film may not have ferroelectric characteristics. For example, when the ferroelectric material film and the paraelectric material film include hafnium oxide, a crystal structure of hafnium oxide included in the ferroelectric material film is different from that of hafnium oxide included in the paraelectric material film.

The ferroelectric material film may have a thickness having ferroelectric characteristics. The thickness of the ferroelectric material film may be, for example, 0.5 nm to 10 nm, but is not limited thereto. Since a threshold thickness indicating ferroelectric characteristics may be varied depending on each ferroelectric material, the thickness of the ferroelectric material film may be varied depending on the ferroelectric material.

For example, the gate insulating film 130 may include one ferroelectric material film. For another example, the gate insulating film 130 may include a plurality of ferroelectric material films spaced apart from each other. The gate insulating film 130 may have a stacked layer structure in which a plurality of ferroelectric material films and a plurality of paraelectric material films are alternately stacked.

A gate spacer 140 may be disposed on a sidewall of the gate electrode 120. The gate spacer 140 may not be disposed between the first sheet pattern NS1 and the second sheet pattern NS2 and between the second sheet pattern NS2 and the third sheet pattern NS3.

The gate spacer 140 may include, for example, silicon nitride, silicon oxynitride, silicon oxide, silicon oxycarbonitride, silicon boron nitride, silicon oxyboronitride, silicon oxycarbide, or a combination thereof. Although the gate spacer 140 is shown as a single film, it is only for convenience of description, and is not limited thereto.

The inner spacer 140ISP may be disposed between the first sheet pattern NS1 and the second sheet pattern NS2 and between the second sheet pattern NS2 and the third sheet pattern NS3. The inner spacer 140ISP may be disposed between the inner gate structure GS_INT and the source/drain pattern 150.

The inner spacer 140ISP may be in contact with the gate insulating film 130 included in the inner gate structure GS_INT. Although the inner spacer 140ISP is shown to be in contact with the source/drain pattern 150, embodiments of the disclosure are not limited thereto.

The inner spacer 140ISP may include a second insulating material. The second insulating material may include, for example, a silicon nitride-based insulating material. In the fabricating process, the inner spacer 140ISP may be formed simultaneously with the lower insulating pattern 160. That is, the second insulating material may be the same as the first insulating material. The second insulating material may include one from among silicon oxynitride, silicon oxycarbonitride, and silicon carbonitride. For example, the second insulating material may be silicon oxycarbonitride. The inner spacer 140ISP may include silicon oxycarbonitride.

A gate capping pattern 145 may be disposed on the gate electrode 120 and the gate spacer 140. An upper surface of the gate capping pattern 145 may be disposed on the same plane as an upper surface of the first interlayer insulating layer 190, but is not limited thereto. According to an embodiment, the gate capping pattern 145 may be disposed between a plurality of the gate spacers 140.

The gate capping pattern 145 may include, for example, silicon nitride, silicon oxynitride, silicon carbonitride, silicon oxycarbonitride, or a combination thereof. The gate capping pattern 145 may include a material having etching selectivity with respect to the first interlayer insulating layer 190.

According to an embodiment, the gate capping pattern 145 may not be disposed on the gate electrode 120.

The source/drain pattern 150 may be disposed on the first lower pattern BP1. The source/drain pattern 150 may be connected to the channel pattern CH. The source/drain pattern 150 may be connected to the first sheet pattern NS1, the second sheet pattern NS2, and the third sheet pattern NS3.

The source/drain pattern 150 may be disposed on a side of the gate structure GS. The source/drain pattern 150 may be disposed between the gate structures GS adjacent to each other in the first direction DR1. For example, the source/drain pattern 150 may be disposed on opposite sides of the gate structures GS. According to an embodiment, the source/drain pattern 150 may be disposed on one side of the gate structure GS, and may not be disposed on the other side of the gate structure GS.

The source/drain pattern 150 may include an epitaxial pattern. The source/drain pattern 150 includes a semiconductor material.

The source/drain pattern 150 may include, for example, silicon or germanium, which is an elemental semiconductor material. Further, the source/drain pattern 150 may include, for example, a binary compound or ternary compound, which includes at least two from among carbon (C), silicon (Si), germanium (Ge) and tin (Sn), or a compound including at least two from among carbon (C), silicon (Si), germanium (Ge) and tin (Sn), which are doped with a group IV element. For example, when the source/drain pattern 150 is included in a source/drain region of a p-type transistor, the source/drain pattern 150 may include silicon-germanium. In another example, when the source/drain pattern 150 is included in a source/drain region of an n-type transistor, the source/drain pattern 150 may include silicon, but is not limited thereto.

The source/drain pattern 150 may include impurities doped into a semiconductor material. For example, when the source/drain pattern 150 is included in the source/drain region of the p-type transistor, the source/drain pattern 150 may include a p-type impurity. For example, the p-type impurity may include at least one from boron (B) and gallium (Ga). In another example, when the source/drain pattern 150 is included in the source/drain region of the n-type transistor, the source/drain pattern 150 may include an n-type impurity. For example, the n-type impurity may include at least one from among phosphorus (P), arsenic (As), antimony (Sb), and bismuth (Bi).

The source/drain pattern 150 is shown to be a single film, but it is only for convenience of description, and is not limited thereto.

A bottom insulating spacer 150BSP may be disposed below the source/drain pattern 150. In other words, the source/drain pattern 150 may be disposed on the bottom insulating spacer 150BSP.

The bottom insulating spacer 150BSP may overlap with the source/drain pattern 150 in the third direction DR3. The bottom insulating spacer 150BSP may be disposed between the source/drain pattern 150 and the first lower pattern BP1.

The bottom insulating spacer 150BSP may be in contact with the lower insulating pattern 160. For example, the bottom insulating spacer 150BSP may be in contact with the sidewall 160_SW of the lower insulating pattern 160. When viewed from a cross-sectional view as shown in FIG. 2, the bottom insulating spacer 150BSP may cover at least a portion of the sidewall 160_SW of the lower insulating pattern.

The bottom insulating spacer 150BSP may include an upper surface 150BSP_US facing the source/drain pattern 150. In the semiconductor device according to some embodiments, the upper surface 150BSP_US of the bottom insulating spacer 150BSP may be flat in a cross-sectional view. Although the upper surface 150BSP_US of the bottom insulating spacer 150BSP is shown as being in contact with the source/drain pattern 150, embodiments of the disclosure are not limited thereto.

The upper surface 150BSP_US of the bottom insulating spacer 150BSP may include a contact uppermost portion 150BSP_UCP. The contact uppermost portion 150BSP_UCP of the bottom insulating spacer 150BSP may be a point closest to the sidewall 160_SW of the lower insulating pattern 160 in the first direction DR1. For example, a distance between the contact uppermost portion 150BSP_UCP of the bottom insulating spacer 150BSP and the sidewall 160_SW of the lower insulating pattern 160 in the first direction DR1 may be 0.

For example, the contact uppermost portion 150BSP_UCP of the bottom insulating spacer 150BSP may be positioned on a contact surface between the bottom insulating spacer 150BSP and the lower insulating pattern 160. When the lower insulating pattern 160 is in contact with a sidewall of the first sheet pattern NS1, the contact uppermost portion 150BSP_UCP of the bottom insulating spacer 150BSP is not positioned on the contact surface between the bottom insulating spacer 150BSP and the lower insulating pattern 160.

The bottom insulating spacer 150BSP may cover a portion of the sidewall 160_SW of the lower insulating pattern 160. The bottom insulating spacer 150BSP may be in contact with a portion of the sidewall 160_SW of the lower insulating pattern 160. In the semiconductor device according to some embodiments, a height H1 from the second surface 160_BS of the lower insulating pattern 160 to the contact uppermost portion 150BSP_UCP of the bottom insulating spacer 150BSP may be less than a height t1 from the second surface 160_BS of the lower insulating pattern 160 to the first surface 160_US of the lower insulating pattern 160. A height from the second surface 160_BS of the lower insulating pattern 160 to the first surface 160_US of the lower insulating pattern 160 may be a thickness t1 of the lower insulating pattern 160 in the third direction DR3.

The bottom insulating spacer 150BSP may include a third insulating material. The third insulating material may include, for example, a silicon nitride-based insulating material. The third insulating material may be different from the first insulating material included in the lower insulating pattern 160. For example, the third insulating material may be silicon nitride. The bottom insulating spacer 150BSP may include silicon nitride.

A dielectric constant of the third insulating material included in the bottom insulating spacer 150BSP may be greater than a dielectric constant of the first insulating material included in the lower insulating pattern 160. Since silicon nitride includes oxygen (O) or carbon (C), a dielectric constant of the first insulating material included in the lower insulating pattern 160 may be smaller than a dielectric constant of the third insulating material included in the bottom insulating spacer 150BSP.

A leakage current between adjacent source/drain patterns 150 may be blocked through the bottom insulating spacer 150BSP and the lower insulating pattern 160. As a result, performance and reliability of the semiconductor device may be improved.

The source/drain etching stop film 185 may be disposed on a sidewall of the gate spacer 140 and on an upper surface of the source/drain pattern 150. Although not shown, the source/drain etching stop film 185 may be disposed on the upper surface of the field insulating layer 105.

The source/drain etching stop film 185 may include a material having etching selectivity with respect to the first interlayer insulating layer 190 that will be described later. The source/drain etching stop film 185 may include, for example, silicon nitride, silicon oxynitride, silicon oxycarbonitride, silicon boron nitride, silicon oxyboronitride, silicon oxycarbide, or a combination thereof.

The first interlayer insulating layer 190 may be disposed on the source/drain etching stop film 185. The first interlayer insulating layer 190 may be disposed on the first source/drain pattern 150. The first interlayer insulating layer 190 may not cover the upper surface of the gate capping pattern 145 (e.g., a first gate capping pattern).

The first interlayer insulating layer 190 may include at least one from among, for example, silicon oxide, silicon nitride, silicon oxynitride, and a low dielectric constant material. The low dielectric constant material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoxySiloxane (DADBS), TriMethylSilyl Phosphate (TMSP), PolyTetraFluoroEthylene (PTFE), Tonen SilaZen (TOSZ), Fluoride Silicate Glass (FSG), polyimide nanofoams such as polypropylene oxide, Carbon Doped Silicon Oxide (CDO), Organo Silicate Glass (OSG), SiLK, Amorphous Fluorinated Carbon, silica aerogels, silica xerogels, mesoporous silica, or a combination thereof, but the is not limited thereto.

A frontside source/drain contact 180 may be disposed on the source/drain pattern 150. The frontside source/drain contact 180 may be connected to the source/drain pattern 150. The frontside source/drain contact 180 may be connected to the source/drain pattern 150 by passing through the first interlayer insulating layer 190 and the source/drain etching stop film 185.

Although the frontside source/drain contact 180 is shown as a single layer, it is only for convenience of description, and is not limited thereto. The frontside source/drain contact 180 may include, for example, metal, a conductive metal nitride, a conductive metal carbide, a conductive metal oxide, a conductive metal carbonitride, a two-dimensional (2D) material, or a combination thereof. In the semiconductor device according to some embodiments, the two-dimensional material may be a metallic material and/or a semiconductor material. The 2D material may contain a two-dimensional allotrope or a two-dimensional compound, and may contain at least one from among, for example, graphene, molybdenum disulfide (MoS₂), molybdenum diselenide (MoSe₂), tungsten diselenide (WSe₂), and tungsten disulfide (WS₂), but is not limited thereto. That is, since the two-dimensional materials described above are only examples, the two-dimensional material that may be contained in the semiconductor memory device of embodiments of the disclosure is not limited by the above-described materials.

A frontside contact silicide film 151 may be further disposed between the frontside source/drain contact 180 and the source/drain pattern 150. The frontside contact silicide film 151 may include metal silicide.

The second interlayer insulating layer 191 may be disposed on the first interlayer insulating layer 190. For example, the second interlayer insulating layer 191 may include at least one from among silicon oxide, silicon nitride, silicon oxynitride, and a low dielectric constant material.

The frontside wiring structure 205 may be disposed in the second interlayer insulating layer 191. The frontside wiring structure 205 may be connected to the frontside source/drain contact 180. The frontside wiring structure 205 may include a frontside wiring line 207 and a frontside wiring via 206.

Although the frontside wiring line 207 and the frontside wiring via 206 are shown as being distinguished from each other, this is only for convenience of description, and are not limited thereto. That is, for example, after the frontside wiring via 206 is formed, the frontside wiring line 207 may be formed. In another example, the frontside wiring via 206 and the frontside wiring line 207 may be formed simultaneously.

Although each of the frontside wiring line 207 and the frontside wiring via 206 is shown as a single layer, it is only for convenience of description, and is not limited thereto. Each of the frontside wiring line 207 and the frontside wiring via 206 may include at least one from among, for example, metal, a conductive metal nitride, a conductive metal carbide, a conductive metal oxide, a conductive metal carbonitride, and a two-dimensional (2D) material.

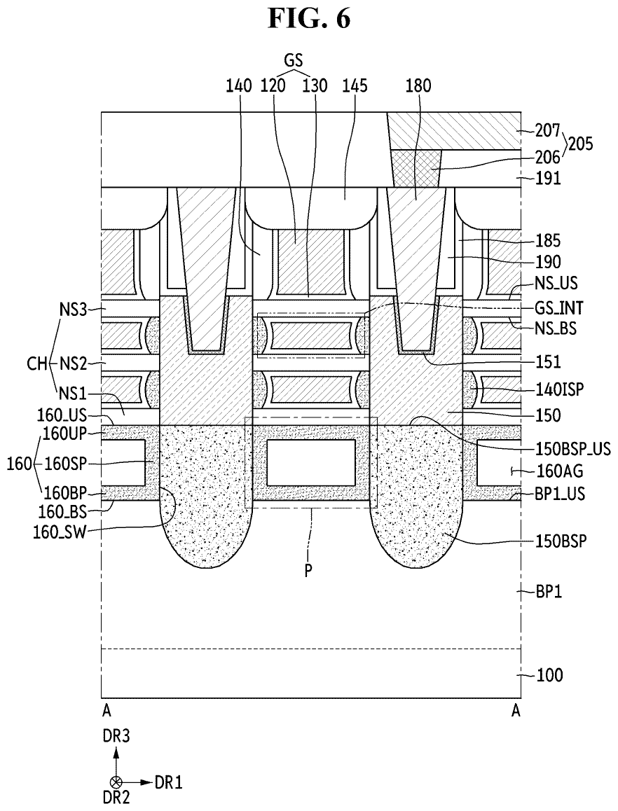

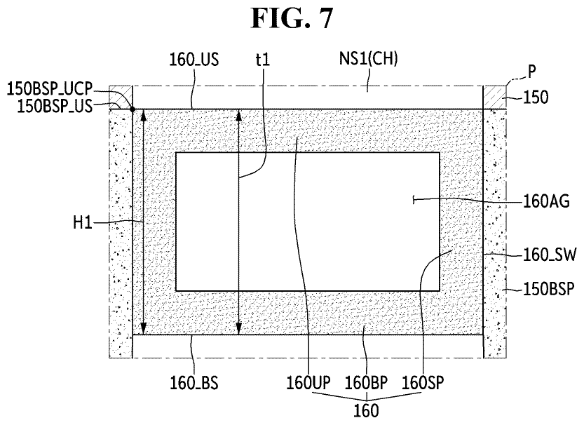

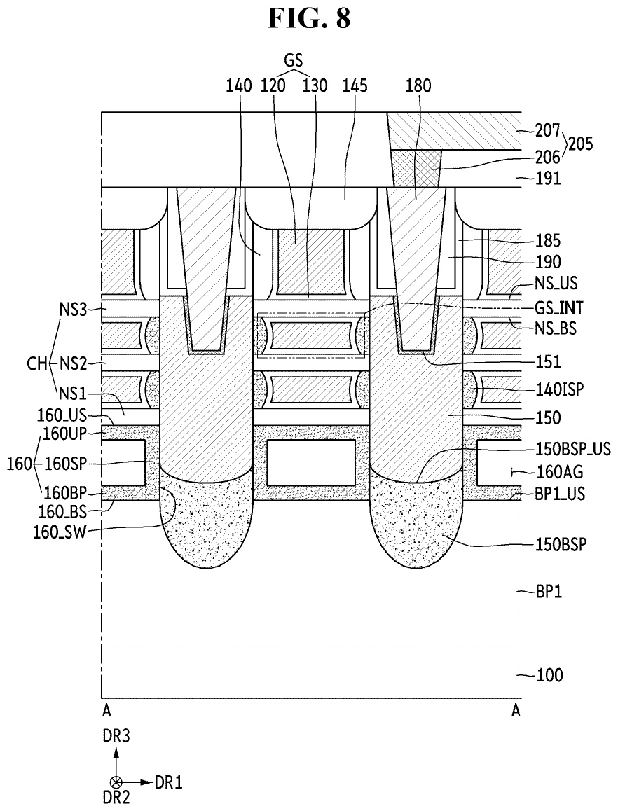

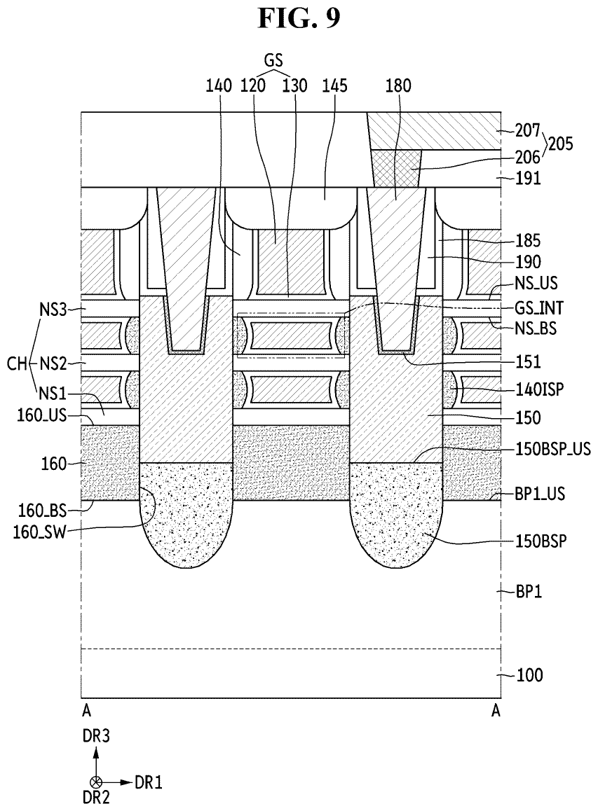

FIGS. 6 and 7 are views illustrating a semiconductor device according to some embodiments. FIGS. 8 and 9 are views illustrating a semiconductor device according to some embodiments, respectively. For convenience of description, the following description will be based on differences from the description made with reference to reference to FIGS. 1 to 5. For reference, FIG. 7 is an enlarged view of a portion P of FIG. 6.

Referring to FIGS. 6 and 7, in the semiconductor device according to some embodiments, the bottom insulating spacer 150BSP may fully cover the sidewall 160_SW of the lower insulating pattern 160.

When viewed from a cross-sectional view, the bottom insulating spacer 150BSP may be in contact with the entire sidewall of the lower insulating pattern 160_SW. The height H1 from the second surface 160_BS of the lower insulating pattern 160 to the contact uppermost portion 150BSP_UCP of the bottom insulating spacer 150BSP may be the same as the height t1 from the second surface 160_BS of the lower insulating pattern 160 to the first surface 160_US of the lower insulating pattern 160.

Referring to FIG. 8, in the semiconductor device according to some embodiments, the upper surface 150BSP_US of the bottom insulating spacer 150BSP may include a curved surface when viewed from a cross-sectional view.

For example, when viewed from a cross-sectional view, the upper surface of the bottom insulating spacer 150BSP_US may have a concave shape.

Referring to FIG. 9, in the semiconductor device according to some embodiments, the lower insulating pattern 160 may not include an air gap (e.g., air gap 160AG of FIG. 2) disposed therein.

According to an embodiment, the lower insulating pattern 160 may include a seam pattern.

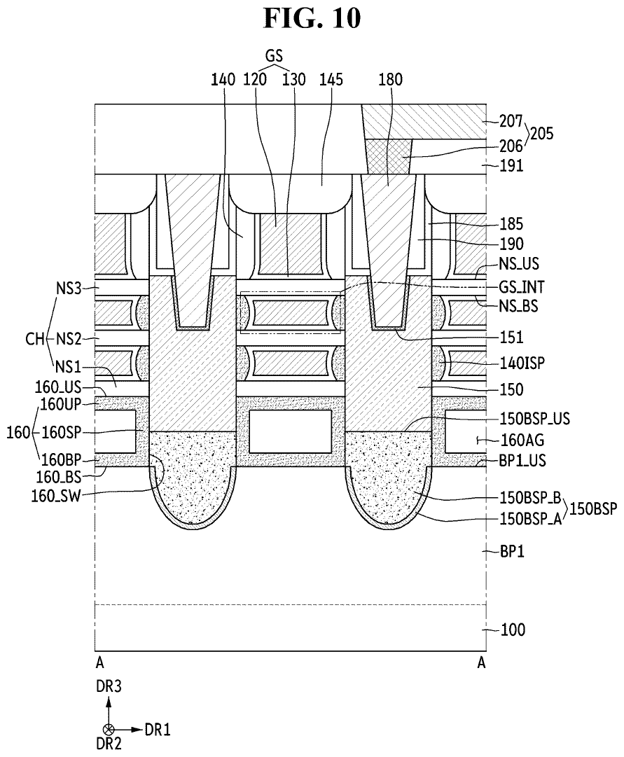

FIG. 10 is a view illustrating a semiconductor device according to some embodiments. For convenience of description, the following description will be based on differences from the description made with reference to reference to FIGS. 1 to 5.

Referring to FIG. 10, in the semiconductor device according to some embodiments, the bottom insulating spacer 150BSP may include a first sub-bottom insulating spacer 150BSP_A and a second sub-bottom insulating spacer 150BSP_B.

The second sub-bottom insulating spacer 150BSP_B may be disposed between the first sub-bottom insulating spacer 150BSP_A and the source/drain pattern 150. The first sub-bottom insulating spacer 150BSP_A may be in contact with the second sub-bottom insulating spacer 150BSP_B.

The first sub-bottom insulating spacer 150BSP_A may have a liner shape. The first sub-bottom insulating spacer 150BSP_A may extend up to the upper surface BP1_US of the first lower pattern BP1. The first sub-bottom insulating spacer 150BSP_A may not protrude past, in the third direction DR3, the upper surface BP1_US of the first lower pattern BP1. The first sub-bottom insulating spacer 150BSP_A may not extend along the sidewall 160_SW of the lower insulating pattern 160.

A plurality of first sub-bottom insulating spacers 150BSP_A, which are adjacent to each other in the first direction DR1, may not be directly connected to each other. At least a portion of the second surface 160_BS of the lower insulating pattern 160 may not overlap the first sub-bottom insulating spacer 150BSP_A in the third direction DR3.

The second sub-bottom insulating spacer 150BSP_B may include the upper surface of the bottom insulating spacer 150BSP_US. The second sub-bottom insulating spacer 150BSP_B may be in contact with at least a portion of the sidewall 160_SW of the lower insulating pattern 160. The second sub-bottom insulating spacer 150BSP_B may cover the uppermost portion of the first sub-bottom insulating spacer 150BSP_A.

The first sub-bottom insulating spacer 150BSP_A may include, for example, a semiconductor material. For example, the first sub-bottom insulating spacer 150BSP_A may include silicon-germanium doped with carbon (C).

The second sub-bottom insulating spacer 150BSP_B may include a third insulating material included in the bottom insulating spacer 150BSP described with reference to FIGS. 1 to 5.

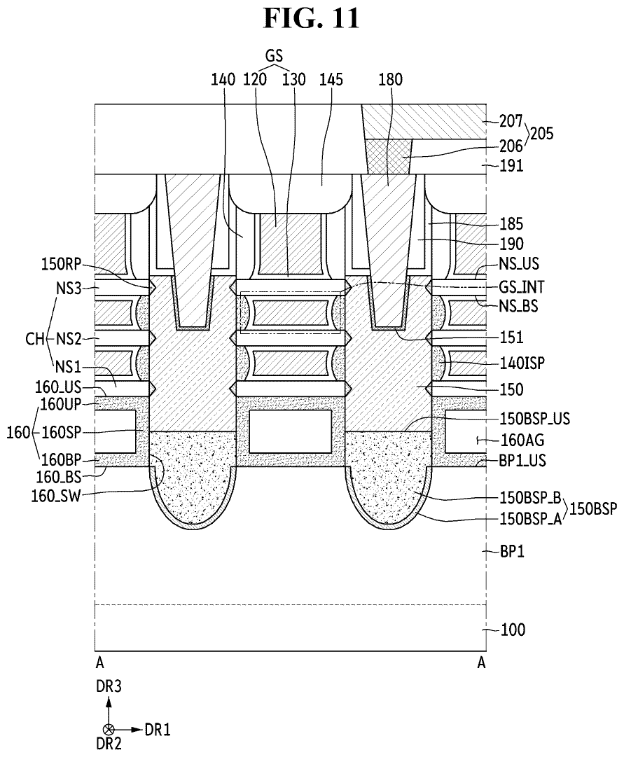

FIG. 11 is a view illustrating a semiconductor device according to some embodiments. For convenience of description, the following description will be based on differences from the description made with reference to reference to FIG. 10.

Referring to FIG. 11, the semiconductor device according to some embodiments may further include a residual semiconductor pattern 150RP disposed between the channel pattern CH and the source/drain pattern 150.

The residual semiconductor pattern 150RP may be disposed between the first sheet pattern NS1 and the source/drain pattern 150, between the second sheet pattern NS2 and the source/drain pattern 150, and between the third sheet pattern NS3 and the source/drain pattern 150. The residual semiconductor pattern 150RP may be in contact with the first sheet pattern NS1, the second sheet pattern NS2, and the third sheet pattern NS3. The residual semiconductor pattern 150RP may be in contact with the source/drain pattern 150.

The residual semiconductor pattern 150RP may be formed while the first sub-bottom insulating spacer 150BSP_A is being formed. The residual semiconductor pattern 150RP may include, for example, silicon-germanium doped with carbon (C).

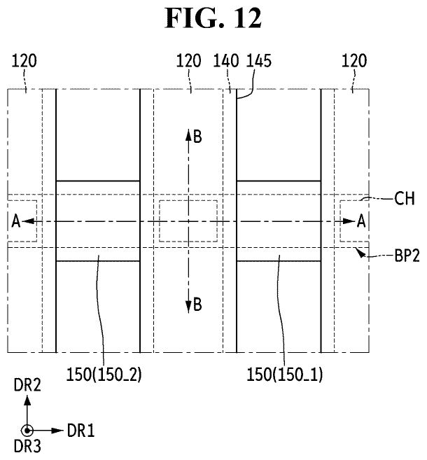

FIGS. 12 to 14 are views illustrating a semiconductor device according to some embodiments. For convenience of description, the following description will be based on differences from the description made with reference to reference to FIGS. 1 to 5.

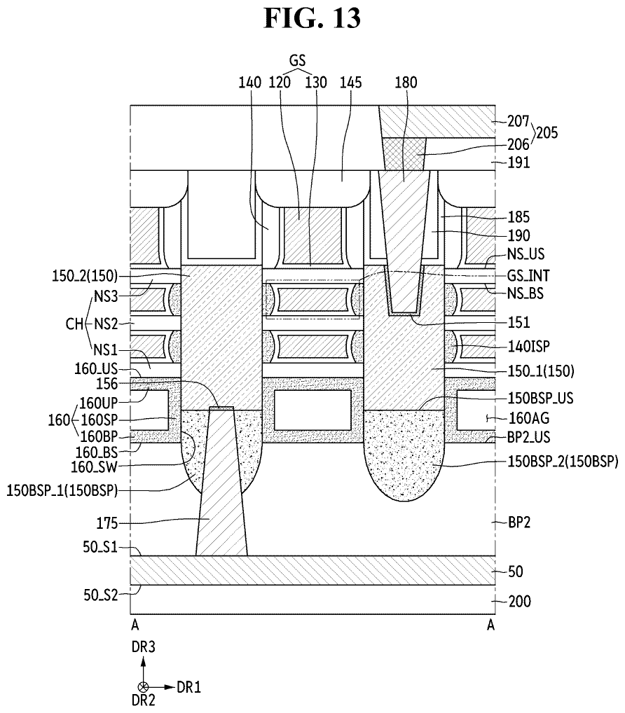

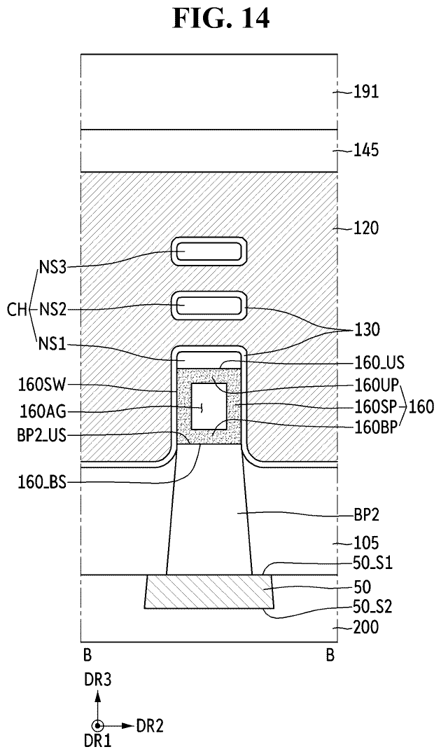

For reference, FIG. 12 is an example plan view illustrating a semiconductor device according to some embodiments. FIGS. 13 and 14 are cross-sectional views taken along a line A-A and a line B-B of FIG. 12.

Referring to FIGS. 12 to 14, the semiconductor device according to some embodiments may include a backside wiring line 50, a backside source/drain contact 175, a second lower pattern BP2, a channel pattern CH, a gate electrode 120, an inner spacer 140ISP, a bottom insulating spacer 150BSP, a lower insulating pattern 160, and a source/drain pattern 150.

The description of the channel pattern CH, the gate electrode 120, the inner spacer 140ISP, the bottom insulating spacer 150BSP, the lower insulating pattern 160, and the source/drain pattern 150 may be the same as the description made with reference to FIGS. 1 to 5, and thus the following description will be based on differences from FIGS. 1 to 5.

A second substrate 200 may be provided and include an insulating material. The second substrate 200 may include at least one from among silicon oxide, silicon nitride, and silicon oxynitride, but is not limited thereto.

The backside wiring line 50 may be disposed in or on the second substrate 200. The backside wiring line 50 may extend in the first direction DR1.

As an example, the backside wiring line 50 may be a power line that supplies a power source to the semiconductor device. As another example, the backside wiring line 50 may be a signal line that supplies an operation signal of the semiconductor device.

The backside wiring line 50 may include a first surface 50_S1 and a second surface 50_S2, which may be opposite to each other in the third direction DR3. The first surface 50_S1 of the backside wiring line 50 may face towards the source/drain pattern 150.

The backside wiring line 50 is shown as having a trapezoidal cross-section, but is not limited thereto. According to an embodiment, the backside wiring line 50 may have a rectangular cross-section. A width of the first surface 50_S1 of the backside wiring line 50 in the second direction DR2 may be smaller than a width of the second surface 50_S2 of the backside wiring line 50 in the second direction DR2.

For example, the backside wiring line 50 may be formed using a damascene process. After a trench extended in the first direction DR1 is formed on the second substrate 200, the backside wiring line 50 may be formed by filling the trench with a conductive material.

Although the backside wiring line 50 is shown as having a single conductive film structure, it is only for convenience of description, and is not limited thereto. The backside wiring line 50 may include at least one from among, for example, metal, a conductive metal nitride, a conductive metal carbide, a conductive metal oxide, a conductive metal carbonitride, and a two-dimensional (2D) material.

According to an embodiment, the backside wiring line 50 may extend in the second direction DR2. In this case, a shape of the cross-sectional view taken along the line A-A and the line B-B of FIG. 12 may vary.

According to an embodiment, the backside wiring line 50 may include a line portion and a via portion. In this case, the line portion of the backside wiring line 50 may extend in the first direction DR1. The via portion of the backside wiring line 50 may protrude from the line portion of the backside wiring line 50 in the third direction DR3. The via portion of the backside wiring line 50 may protrude toward the backside source/drain contact 175.

The second lower pattern BP2 may protrude from the second substrate 200 in the third direction DR3. The second lower pattern BP2 may extend in the first direction DR1. The second lower pattern BP2 may be disposed on the first surface 50_S1 of the backside wiring line 50.

For example, the second lower pattern BP2 may include silicon or germanium, which is an elemental semiconductor material. Alternatively, the second lower pattern BP2 may include a compound semiconductor.

In another example, the second lower pattern BP2 may include an insulating material. The second lower pattern BP2 may include at least one from among silicon oxide, silicon nitride, and silicon oxynitride. The field insulating layer 105 may be disposed on a sidewall of the second lower pattern BP2. When the field insulating layer 105 and the second lower pattern BP2 include the same insulating material as each other, a boundary between the field insulating layer 105 and the second lower pattern BP2 may not be distinguished.

The lower insulating pattern 160 may be disposed on the first surface 50_S1 of the backside wiring line 50. The second surface 160_BS of the lower insulating pattern 160 may face the backside wiring line 50.

The backside wiring line 50 may be disposed on the second surface 160_BS of the lower insulating pattern 160. The frontside wiring line 207 may be disposed on the first surface 160_US of the lower insulating pattern 160.

The channel pattern CH may be disposed on the upper surface BP2_US of the second lower pattern BP2. The first sheet pattern NS1, the second sheet pattern NS2, and the third sheet pattern NS3 may be disposed on the upper surface BP2_US of the second lower pattern BP2.

The source/drain pattern 150 may include a first source/drain pattern 150_1 and a second source/drain pattern 150_2. The first source/drain pattern 150_1 and the second source/drain pattern 150_2 may be disposed on the first surface 50_S1 of the backside wiring line 50.

The first source/drain pattern 150_1 and the second source/drain pattern 150_2 may be spaced apart from each other in the first direction DR1 with the channel pattern CH interposed therebetween. Each of the first source/drain pattern 150_1 and the second source/drain pattern 150_2 may be connected to the first sheet pattern NS1, the second sheet pattern NS2, and the third sheet pattern NS3.

The inner spacer 140ISP may be disposed between the inner gate structure GS_INT and the first source/drain pattern 150_1, and between the inner gate structure GS_INT and the second source/drain pattern 150_2.

The bottom insulating spacer 150BSP may include a first bottom insulating spacer 150BSP_1 and a second bottom insulating spacer 150BSP_2. The first bottom insulating spacer 150BSP_1 and the second bottom insulating spacer 150BSP_2 may be spaced apart from each other in the first direction DR1. Each of the first bottom insulating spacer 150BSP_1 and the second bottom insulating spacer 150BSP_2 may be in contact with at least a portion of the sidewall 160_SW of the lower insulating pattern 160.

The first bottom insulating spacer 150BSP_1 may be disposed below the second source/drain pattern 150_2. The first bottom insulating spacer 150BSP_1 may overlap with the second source/drain pattern 150_2 in the third direction DR3. The first bottom insulating spacer 150BSP_1 may be disposed between the backside wiring line 50 and the second source/drain pattern 150_2.

The second bottom insulating spacer 150BSP_2 may be disposed below the first source/drain pattern 150_1. The second bottom insulating spacer 150BSP_2 may overlap with the first source/drain pattern 150_1 in the third direction DR3. The second bottom insulating spacer 150BSP_2 may be disposed between the backside wiring line 50 and the first source/drain pattern 150_1.

The frontside source/drain contact 180 may be connected to the first source/drain pattern 150_1. The frontside contact silicide film 151 may be disposed between the frontside source/drain contact 180 and the first source/drain pattern 150_1. For example, the first source/drain pattern 150_1 may not be connected to the backside wiring line 50.

The backside source/drain contact 175 may be connected to the second source/drain pattern 150_2. For example, the backside source/drain contact 175 may be electrically connected to the second source/drain pattern 150_2.

The backside source/drain contact 175 may be disposed between the second source/drain pattern 150_2 and the backside wiring line 50. The backside source/drain contact 175 may overlap with the backside wiring line 50 and the second source/drain pattern 150_2 in the third direction DR3.

The backside source/drain contact 175 may connect the second source/drain pattern 150_2 to the backside wiring line 50. The backside source/drain contact 175 may be connected to the backside wiring line 50. The backside source/drain contact 175 may be connected to the first surface 50_S1 of the backside wiring line 50.

The backside source/drain contact 175 may be disposed in the second lower pattern BP2. The backside source/drain contact 175 may extend from the first surface 50_S1 of the backside wiring line 50 to the second source/drain pattern 150_2. The backside source/drain contact 175 may be connected to the second source/drain pattern 150_2 by passing through the first bottom insulating spacer 150BSP_1.

According to an embodiment, when the second lower pattern BP2 includes a semiconductor material, a backside contact insulating liner may be further disposed between the backside source/drain contact 175 and the second lower pattern BP2. The backside contact insulating liner may include an insulating material.

Although the backside source/drain contact 175 is shown as a single layer, it is only for convenience of description, and is not limited thereto. The backside source/drain contact 175 may include, for example, metal, a conductive metal nitride, a conductive metal carbide, a conductive metal oxide, or a conductive metal carbonitrie, a two-dimensional (2D) material, or a combination thereof.

A backside contact silicide film 156 may be further disposed between the backside source/drain contact 175 and the second source/drain pattern 150_2. The backside contact silicide film 156 may include metal silicide.

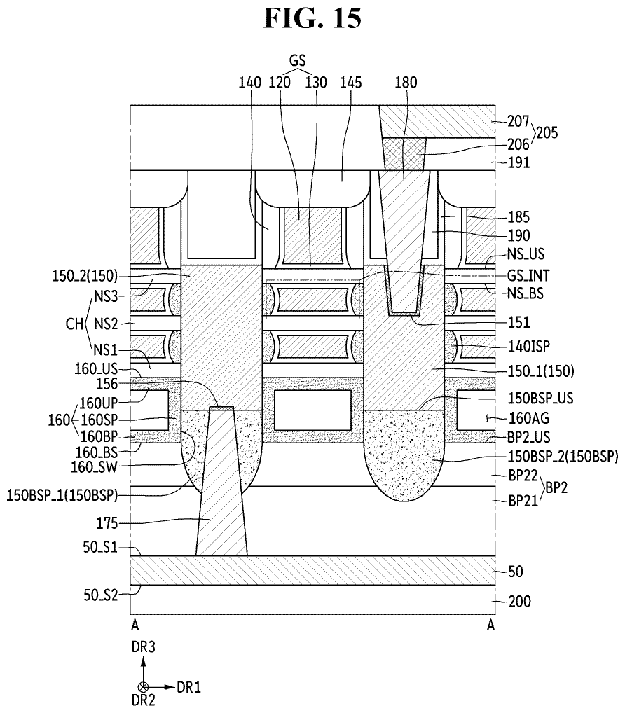

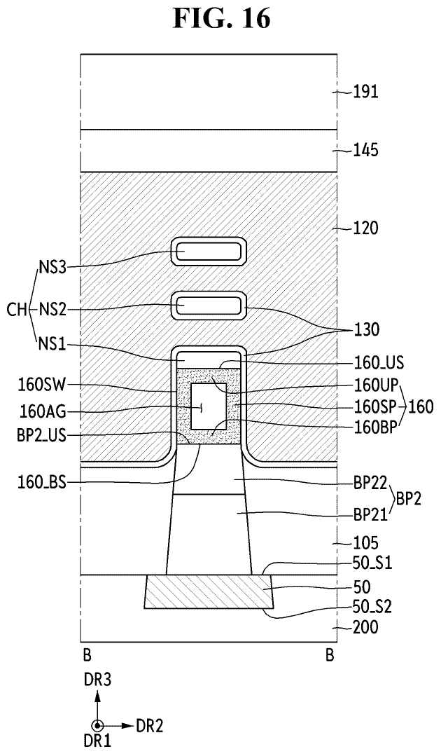

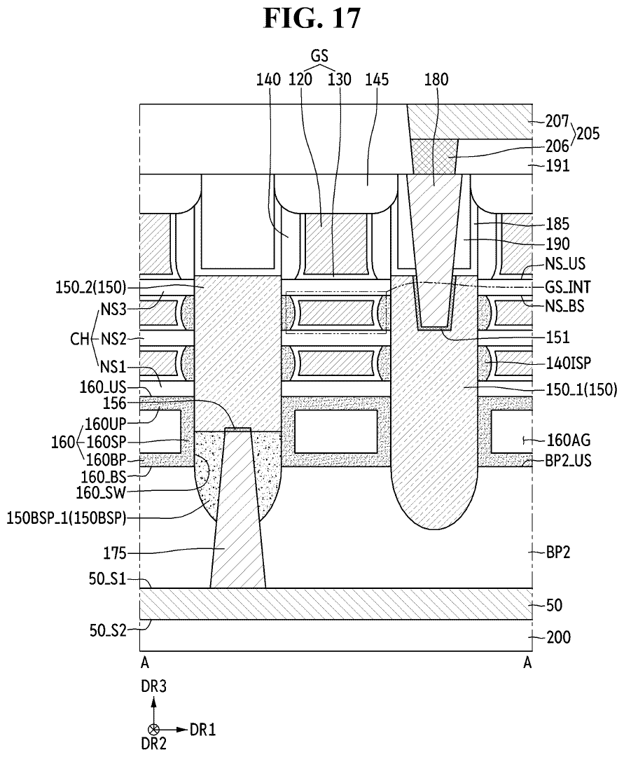

FIGS. 15 and 16 are views illustrating a semiconductor device according to some embodiments. FIG. 17 is a view illustrating a semiconductor device according to some embodiments. For convenience of description, the following description will be based on differences from the description made with reference to FIGS. 12 to 14.

Referring to FIGS. 15 and 16, in the semiconductor device according to some embodiments, the second lower pattern BP2 may include a first sub-lower pattern BP21 and a second sub-lower pattern BP22.

The first sub-lower pattern BP21 may be disposed between the second sub-lower pattern BP22 and the backside wiring line 50. The second sub-lower pattern BP22 may be in contact with the lower insulating pattern 160.

The first sub-lower pattern BP21 may include an insulating material. The second sub-lower pattern BP22 may include a semiconductor material.

Referring to FIG. 17, in the semiconductor device according to some embodiments, the bottom insulating spacer 150BSP may not be disposed below the first source/drain pattern 150_1 that is not connected to the backside wiring line 50.

The bottom insulating spacer 150BSP may not be disposed between the first source/drain pattern 150_1 and the backside wiring line 50. That is, the second bottom insulating spacer (e.g., the second bottom insulating spacer 150BSP_2 of FIG. 13) may not be disposed between the first source/drain pattern 150_1 and the backside wiring line 50.

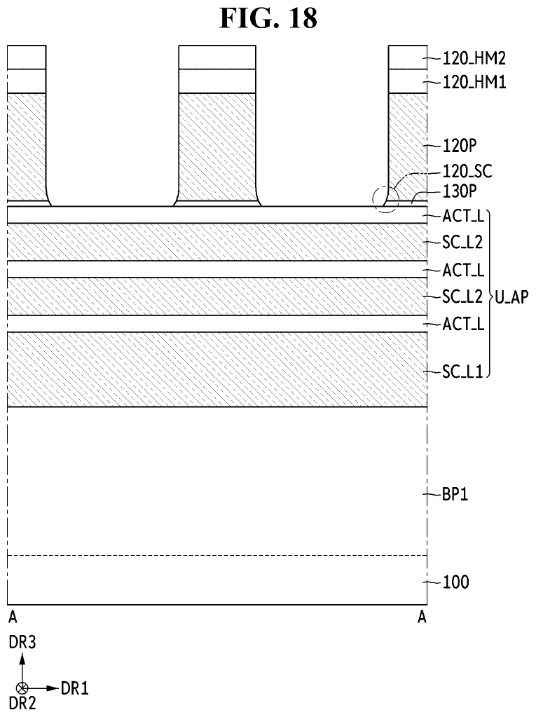

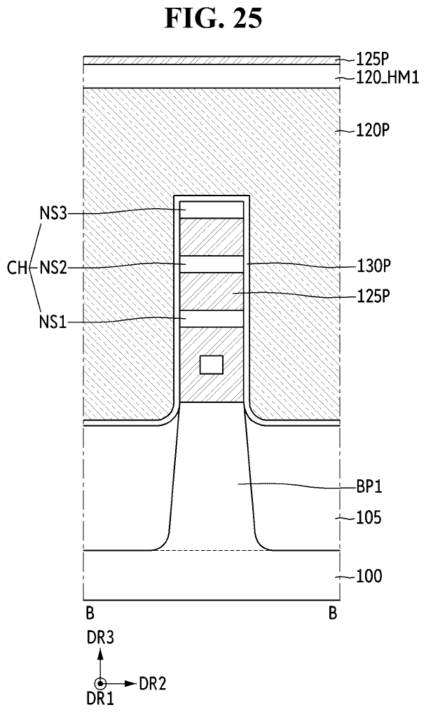

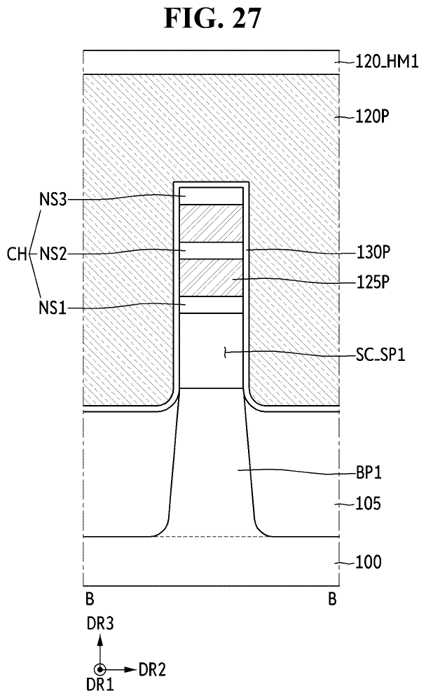

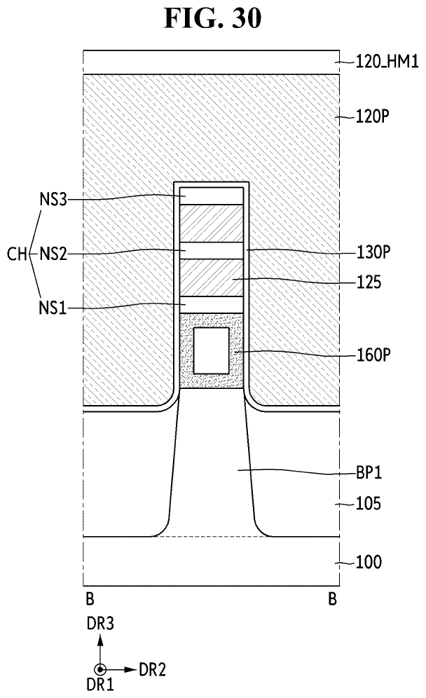

FIGS. 18 to 36 are views illustrating intermediate steps to describe a method for fabricating a semiconductor memory device according to some embodiments.

Referring to FIG. 18, a first lower pattern BP1 and an upper pattern structure U_AP may be formed on the first substrate 100.

The first lower pattern BP1 may extend in the first direction DR1. The upper pattern structure U_AP may be disposed on the first lower pattern BP1.

The upper pattern structure U_AP may include at least one first sacrificial pattern SC_L1, at least one second sacrificial pattern SC_L2, and at least one active pattern ACT_L. The first sacrificial pattern SC_L1 may be disposed between the first lower pattern BP1 and the active pattern ACT_L. The second sacrificial pattern SC_L2 may be disposed between the active patterns ACT_L adjacent to each other in the third direction DR3. A thickness of the first sacrificial pattern SC_L1 may be greater than a thickness of the second sacrificial pattern SC_L2.

For example, each of the first sacrificial pattern SC_L1 and the second sacrificial pattern SC_L2 may include a silicon-germanium layer. The active pattern ACT_L may include a silicon layer.

Subsequently, a dummy gate structure extending in the second direction DR2 may be formed on the first lower pattern BP1 and the upper pattern structure U_AP.

The dummy gate structure may include a dummy gate insulating film 130P, a dummy gate electrode 120P, a lower dummy gate capping layer 120_HM1, and an upper dummy gate capping layer 120_HM2. When viewed in a cross-sectional view, the dummy gate structure may include a skirt region 120_SC formed at a boundary portion between the upper pattern structure U_AP and the dummy gate structure.

The dummy gate insulating film 130P may include, for example, silicon oxide, but is not limited thereto. The dummy gate electrode 120P may include, for example, polysilicon, but is not limited thereto. The lower dummy gate capping layer 120_HM1 may include, for example, silicon nitride, but is not limited thereto. The upper dummy gate capping layer 120_HM2 may include, for example, silicon oxide, but is not limited thereto.

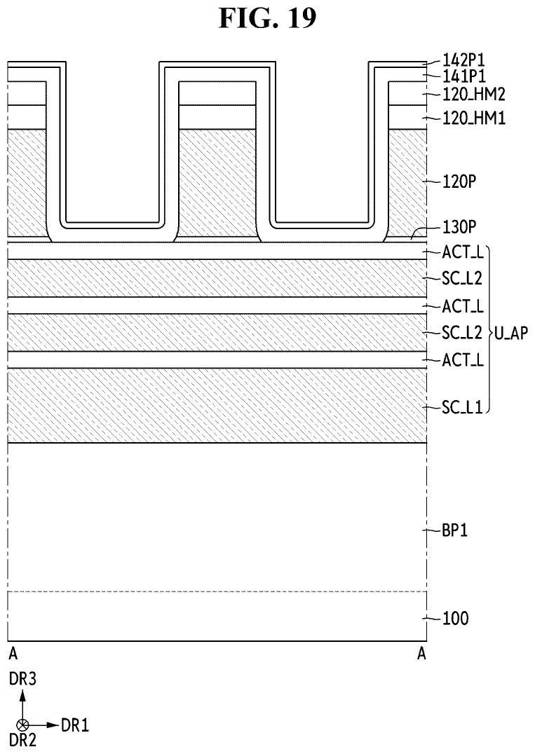

Referring to FIG. 19, a first spacer film 141P1 and a second spacer film 142P1 may be sequentially formed on the upper pattern structure U_AP and the dummy gate structure.

The first spacer film 141P1 and the second spacer film 142P1 may each be formed along a profile of the upper pattern structure U_AP and a profile of the dummy gate structure. The first spacer film 141P1 and the second spacer film 142P1 may be formed along an upper surface of the upper pattern structure U_AP, sidewalls of the dummy gate electrode 120P, and an upper surface of the upper dummy gate capping layer 120_HM2.

Each of the first spacer film 141P1 and the second spacer film 142P1 may include a silicon nitride-based insulating material. For example, the first spacer film 141P1 may include silicon oxycarbonitride, but is not limited thereto. The second spacer film 142P1 may include silicon nitride, but is not limited thereto.

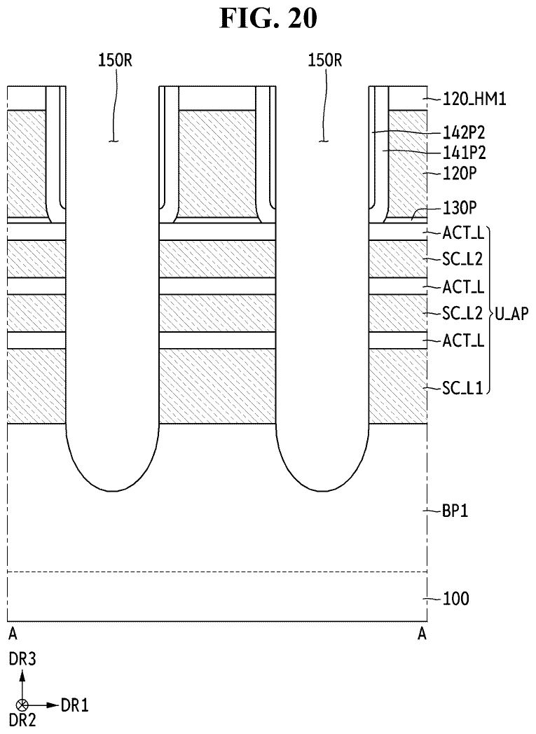

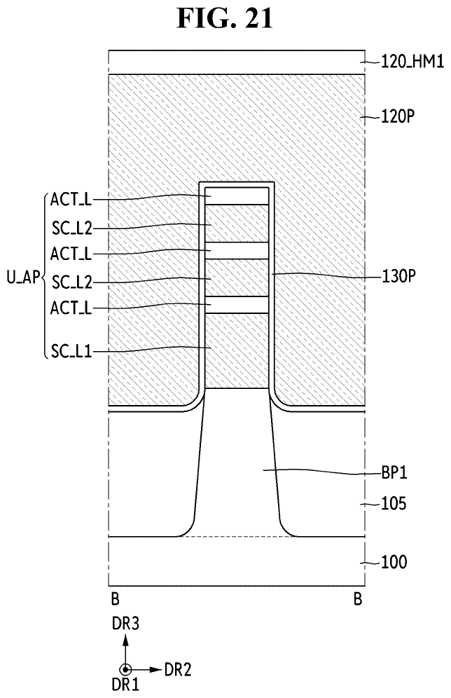

Referring to FIGS. 20 and 21, a plurality of source/drain recesses 150R may be formed in the upper pattern structure U_AP by using the dummy gate electrode 120P as a mask.

In more detail, a source/drain recess 150R may be formed by using the dummy gate insulating film 130P, the dummy gate electrode 120P, the lower dummy gate capping layer 120_HM1 (e.g., a the lower dummy gate capping film), and the upper dummy gate capping layer 120_HM2 (e.g., an upper dummy gate capping film) as etching masks. While the source/drain recess 150R is being formed, the upper dummy gate capping layer 120_HM2 may be removed by an etching process.

A first pre-gate spacer 141P2 and a second pre-gate spacer 142P2 may be formed while the source/drain recess 150R is being formed. The first spacer film 141P1 may be anisotropically etched so that the first pre-gate spacer 141P2 may be formed. The second spacer film 142P1 may be anisotropically etched so that the second pre-gate spacer 142P2 may be formed.

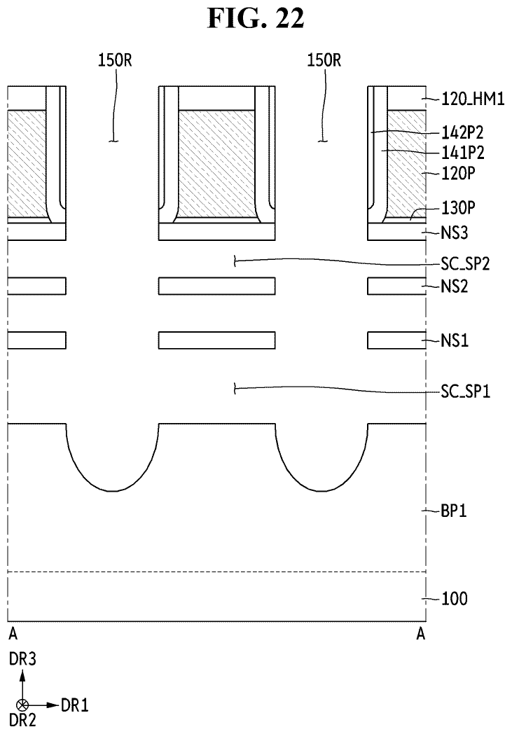

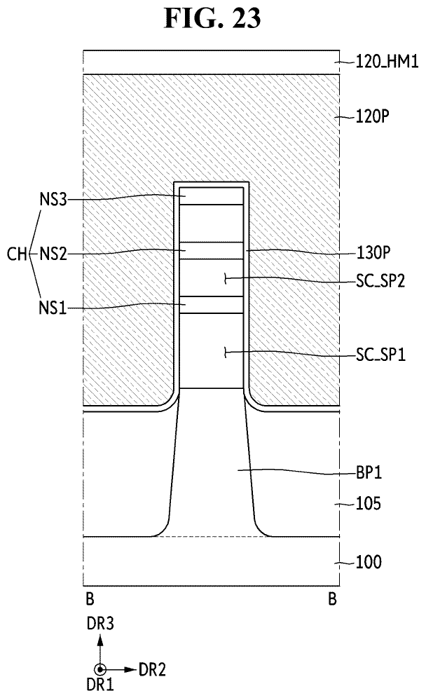

Referring to FIGS. 22 and 23, the first sacrificial pattern SC_L1 and the second sacrificial pattern SC_L2 may be removed so that a first sheet pattern NS1, a second sheet pattern NS2 and a third sheet pattern NS3 may be formed on the first lower pattern BP1.

A channel pattern CH, which includes the first sheet pattern NS1, the second sheet pattern NS2, and the third sheet pattern NS3, may be formed on the first lower pattern BP1.

The first sacrificial pattern SC_L1 may be removed so that a first sacrificial pattern space SC_SP1 may be formed between the first sheet pattern NS1 and the first lower pattern BP1. The second sacrificial pattern SC_L2 may be removed so that a second sacrificial pattern space SC_SP2 may be formed between the first sheet pattern NS1 and the second sheet pattern NS2 and between the second sheet pattern NS2 and the third sheet pattern NS3.

Since a thickness of the first sacrificial pattern SC_L1 is greater than a thickness of the second sacrificial pattern SC_L2, a volume of the first sacrificial pattern space SC_SP1 is greater than a volume of the second sacrificial pattern space SC_SP2.

When viewed in a cross-sectional view, the source/drain recesses 150R adjacent to each other in the first direction DR1 may be connected by the first sacrificial pattern space SC_SP1 and the second sacrificial pattern space SC_SP2.

Referring to FIGS. 22 to 25, a sacrificial insulating film 125P may be formed on the first lower pattern BP1 and the dummy gate electrode 120P.

The sacrificial insulating film 125P may be formed in the first sacrificial pattern space SC_SP1 and the second sacrificial pattern space SC_SP2. The sacrificial insulating film 125P may partially fill the first sacrificial pattern space SC_SP1. The sacrificial insulating film 125P may entirely fill the second sacrificial pattern space SC_SP2. Since the volume of the first sacrificial pattern space SC_SP1 is greater than the volume of the second sacrificial pattern space SC_SP2, the sacrificial insulating film 125P may partially fill the first sacrificial pattern space SC_SP1.

The sacrificial insulating film 125P may be formed on a sidewall and an upper surface of the dummy gate electrode 120P. The sacrificial insulating film 125P may cover sidewalls of the first to third sheet patterns NS1, NS2, and NS3.

The sacrificial insulating film 125P may include silicon oxide, but is not limited thereto.

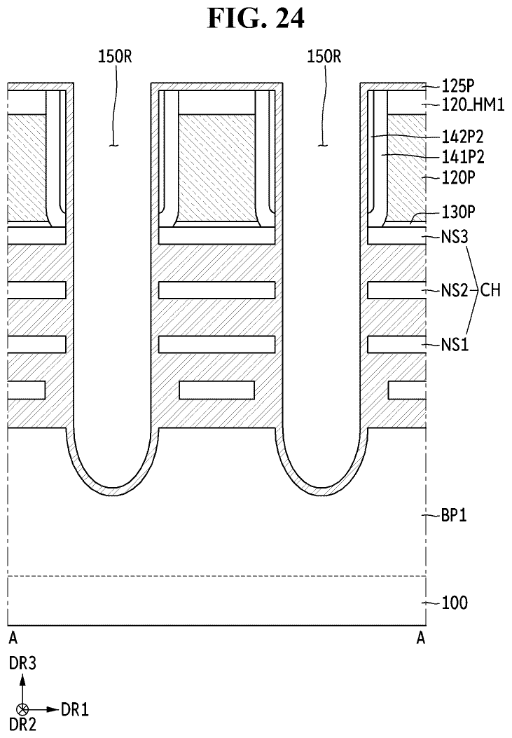

Referring to FIGS. 24 to 27, a portion of the sacrificial insulating film 125P may be removed so that a sacrificial insulating pattern 125 may be formed between the first sheet pattern NS1 and the second sheet pattern NS2 and between the second sheet pattern NS2 and the third sheet pattern NS3.

While the sacrificial insulating pattern 125 is being formed, the sacrificial insulating film 125P on the sidewall and the upper surface of the dummy gate electrode 120P may be removed. While the sacrificial insulating pattern 125 is being formed, the sidewalls of the first to third sheet patterns NS1, NS2, and NS3 may be exposed. While the sacrificial insulating pattern 125 is being formed, the sacrificial insulating film 125P in the first sacrificial pattern space SC_SP1 may be removed.

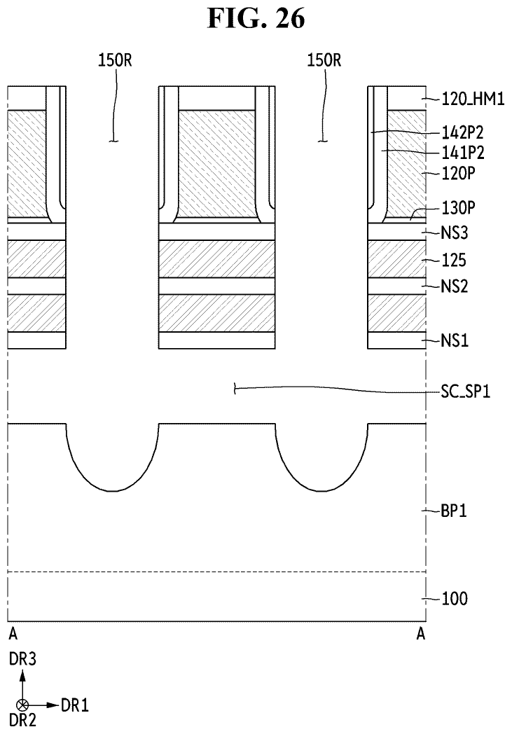

Referring to FIGS. 26 to 28, a portion of the sacrificial insulating pattern 125 may be removed so that a channel dent region may be formed.

The channel dent region may be disposed between the first sheet pattern NS1 and the second sheet pattern NS2 and between the second sheet pattern NS2 and the third sheet pattern NS3.

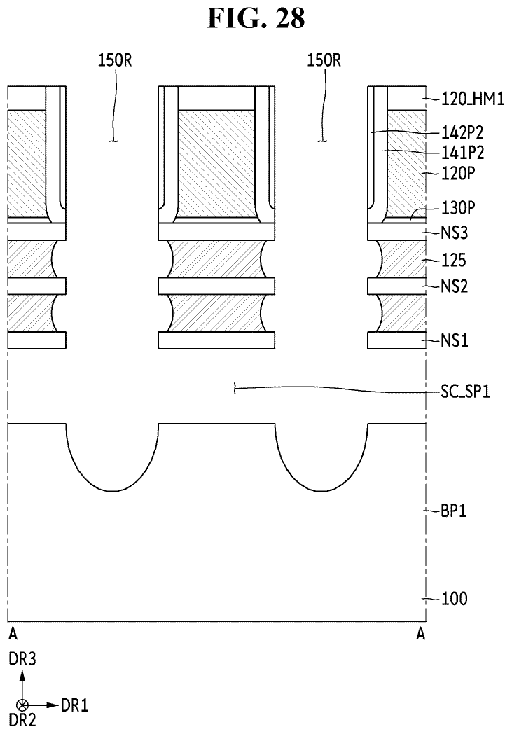

Referring to FIGS. 28 to 30, a lower insulating pattern film 160P may be formed on the first lower pattern BP1 and the dummy gate electrode 120P.

The lower insulating pattern film 160P may be formed in the first sacrificial pattern space SC_SP1. The lower insulating pattern film 160P may fill the channel dent region between the first sheet pattern NS1 and the second sheet pattern NS2 and between the second sheet pattern NS2 and the third sheet pattern NS3. Although the lower insulating pattern film 160P is shown as filling a portion of the first sacrificial pattern space SC_SP1, embodiments of the disclosure are not limited thereto.

The lower insulating pattern film 160P may be formed on the sidewall and the upper surface of the dummy gate electrode 120P. The lower insulating pattern film 160P may cover the sidewalls of the first to third sheet patterns NS1, NS2, and NS3.

The lower insulating pattern film 160P may include a silicon nitride-based insulating material. For example, the lower insulating pattern film 160P may include silicon oxycarbonitride.

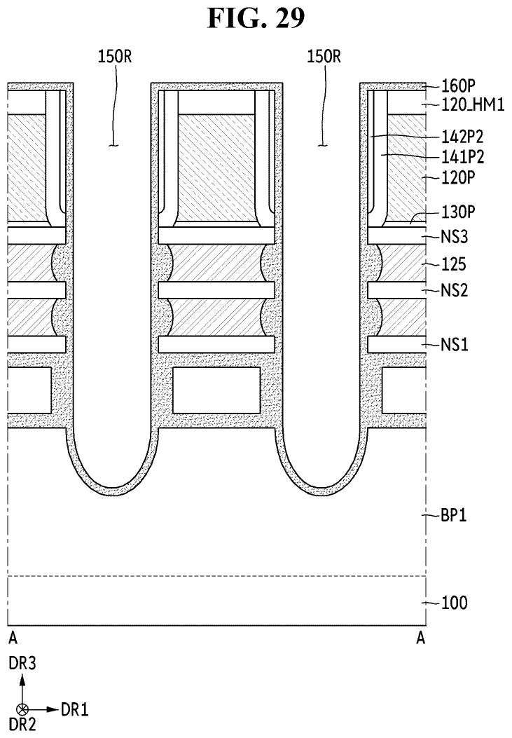

Referring to FIGS. 29 to 31, a portion of the lower insulating pattern layer 160P may be removed so that a lower insulating pattern 160 may be formed between the first lower pattern BP1 and the first sheet pattern NS1.

Although the lower insulating pattern 160 is shown as including an air gap 160AG therein, embodiments of the disclosure are not limited thereto.

While the lower insulating pattern 160 is being formed, the inner spacer 140ISP may be formed between the first sheet pattern NS1 and the second sheet pattern NS2 and between the second sheet pattern NS2 and the third sheet pattern NS3.

While the lower insulating pattern 160 is being formed, the sidewalls of the first to third sheet patterns NS1, NS2, and NS3 may be exposed.

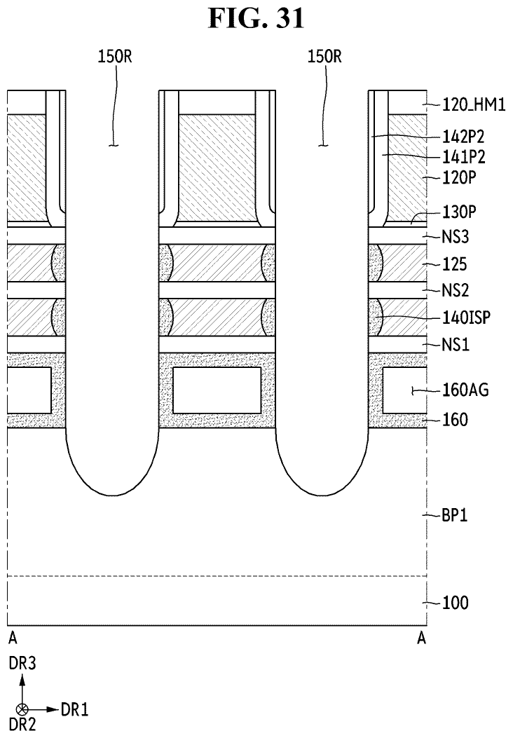

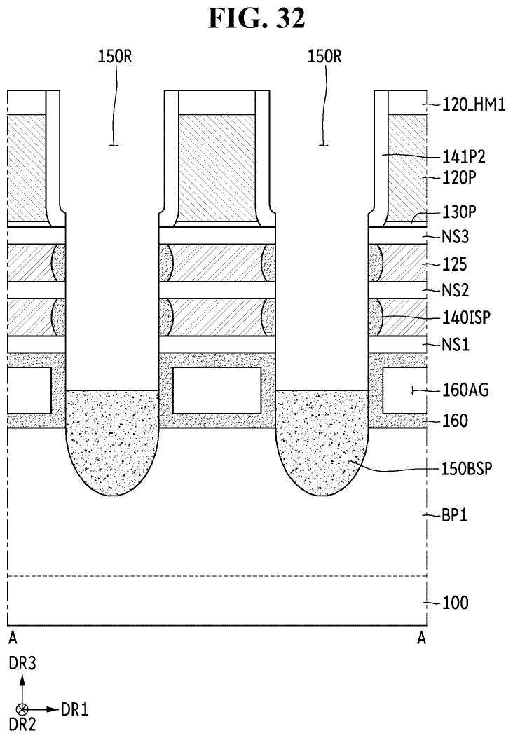

Referring to FIGS. 31 and 32, a bottom insulating spacer 150BSP may be formed in the source/drain recess 150R.

The bottom insulating spacer 150BSP may partially fill the source/drain recess 150R. When the bottom insulating spacer 150BSP includes silicon nitride, the second pre-gate spacer 142P2 may be removed while the bottom insulating spacer 150BSP is being formed, but embodiments of the disclosure are not limited thereto.

Unlike the shown example, a first sub-bottom insulating spacer (e.g., the first sub-bottom insulating spacer 150BSP_A of FIGS. 10 and 11) may be formed. The first sub-bottom insulating spacer 150BSP_A may be formed on the first lower pattern BP1. The first sub-bottom insulating spacer 150BSP_A may be formed by using an epitaxial process. While the first sub-bottom insulating spacer 150BSP_A is being formed, a residual semiconductor pattern (e.g., the residual semiconductor pattern 150RP of FIG. 11) may be formed on the first to third sheet patterns NS1, NS2, and NS3.

For example, after the first sub-bottom insulating spacer 150BSP_A is formed, the residual semiconductor pattern 150RP on the first to third sheet patterns NS1, NS2, and NS3 may be removed. In another example, the residual semiconductor pattern 150RP on the first to third sheet patterns NS1, NS2, and NS3 may not be removed.

Subsequently, a second sub-bottom insulating spacer (e.g., the second sub-bottom insulating spacer 150BSP_B of FIGS. 10 and 11) may be formed on the first sub-bottom insulating spacer 150BSP_A.

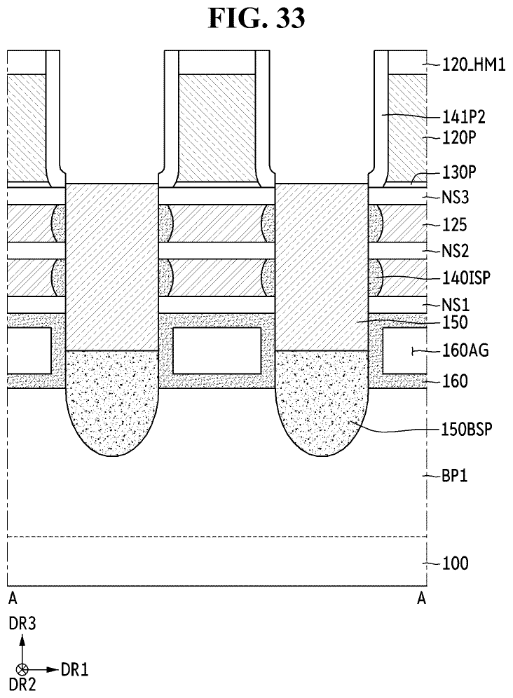

Referring to FIGS. 32 and 33, a source/drain pattern 150 may be formed in the source/drain recess 150R.

The source/drain pattern 150 may be formed on the bottom insulating spacer 150BSP. The source/drain pattern 150 may be connected to the first to third sheet patterns NS1, NS2, and NS3.

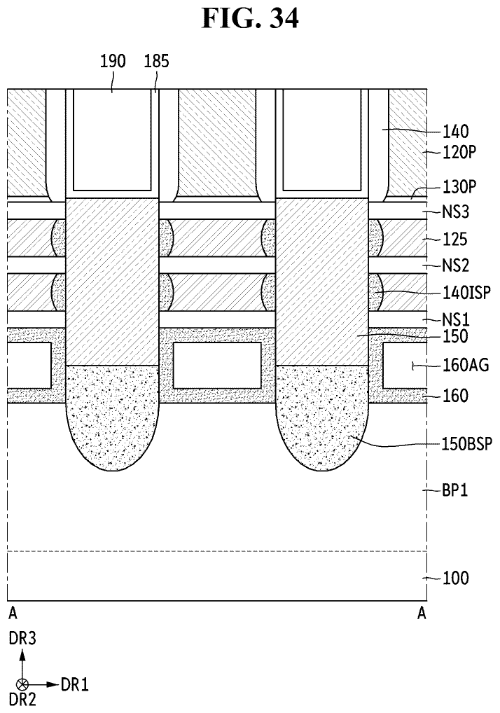

Referring to FIGS. 33 and 34, a source/drain etching stop film 185 and a first interlayer insulating layer 190 may be formed on the source/drain pattern 150.

Subsequently, a portion of the first interlayer insulating layer 190, a portion of the source/drain etching stop film 185, and the lower dummy gate capping layer 120_HM1 may be removed so that the upper surface of the dummy gate electrode 120P is exposed. While the upper surface of the dummy gate electrode 120P is being exposed, a gate spacer 140 may be formed.

According to an embodiment, an additional spacer may be formed on the first pre-gate spacer 141P2 before the source/drain etching stop film 185 is formed. When an additional spacer is not formed on the first pre-gate spacer 141P2, the gate spacer may have an “L” shape similar to that of the first pre-gate spacer 141P2.

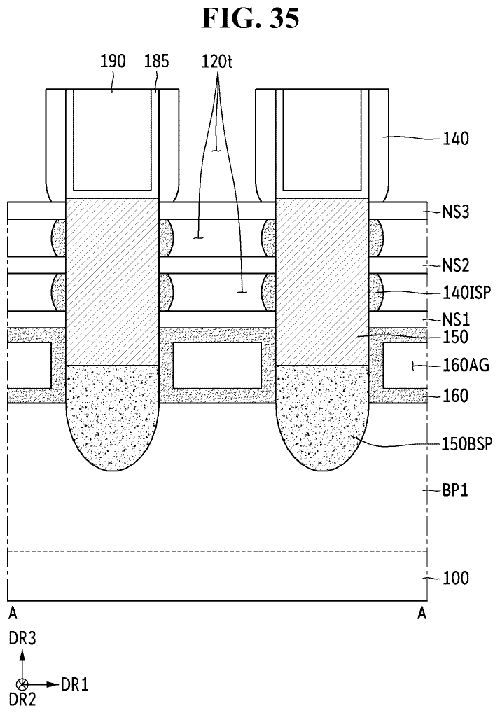

Referring to FIGS. 34 and 35, the dummy gate insulating film 130P and the dummy gate electrode 120P may be removed so that the first to third sheet patterns NS1, NS2, and NS3 and the sacrificial insulating pattern 125 may be exposed.

When the dummy gate insulating film 130P includes the same material as a material of the sacrificial insulating pattern 125, the sacrificial insulating pattern 125 may be also removed while the dummy gate insulating film 130P is being removed.

As a result, a gate trench 120t for exposing the inner spacer 140ISP may be formed.

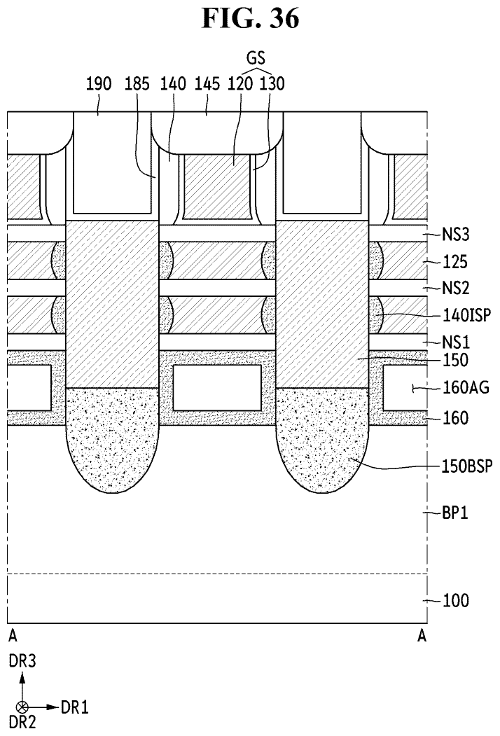

Referring to FIGS. 35 and 36, a gate insulating film 130 and a gate electrode 120 may be formed in the gate trench 120t.

Also, a gate capping pattern 145 may be formed on the gate electrode 120.

Those skilled in the art will appreciate that many variations and modifications may be made to the example embodiments without departing from the spirit and scope of the disclosure. Therefore, embodiments of the disclosure include such variations and modifications, and the disclosure is not limited to the example embodiments that are described.

What is claimed is:

1. A semiconductor device comprising:
a lower insulating pattern comprising:
a first surface;
a second surface opposite to the first surface in a first direction; and
a sidewall connecting the first surface to the second surface;
a first sheet pattern in contact with the first surface of the lower insulating pattern;
a second sheet pattern on the first sheet pattern, spaced apart from the first sheet pattern in the first direction;
a gate structure comprising an inner gate structure, the inner gate structure being between the first sheet pattern and the second sheet pattern, and extending in a second direction that crosses the first direction, and the inner gate structure comprising a gate electrode and a gate insulating film;
a source/drain pattern connected to the first sheet pattern and the second sheet pattern; and
a bottom insulating spacer below the source/drain pattern in the first direction, and overlapped with the source/drain pattern in the first direction,
wherein the bottom insulating spacer comprises a first insulating material, and the lower insulating pattern comprises a second insulating material that is different from the first insulating material, and
wherein a thickness of the inner gate structure in the first direction is smaller than a thickness of the lower insulating pattern in the first direction.

2. The semiconductor device of claim 1, further comprising an inner spacer between the first sheet pattern and the second sheet pattern,
wherein the inner spacer comprises the first insulating material.

3. The semiconductor device of claim 1, wherein the lower insulating pattern includes an air gap.

4. The semiconductor device of claim 1, wherein the bottom insulating spacer is in contact with the sidewall of the lower insulating pattern.

5. The semiconductor device of claim 4, wherein the bottom insulating spacer comprises an upper surface that faces towards the source/drain pattern,
wherein the upper surface of the bottom insulating spacer comprises a contact uppermost portion, the contact uppermost portion being a point of the bottom insulating spacer that is closest to the sidewall of the lower insulating pattern in a third direction that crosses the first direction and the second direction, and
wherein a distance in the first direction from the second surface of the lower insulating pattern to the contact uppermost portion of the bottom insulating spacer is smaller than or equal to a distance in the first direction from the second surface of the lower insulating pattern to the first surface of the lower insulating pattern.

6. The semiconductor device of claim 1, wherein a dielectric constant of the first insulating material is greater than a dielectric constant of the second insulating material.

7. The semiconductor device of claim 6, wherein the first insulating material comprises silicon nitride, and
wherein the second insulating material comprises silicon oxynitride, silicon carbonitride, or silicon oxycarbonitride.

8. The semiconductor device of claim 1, wherein the bottom insulating spacer comprises an upper surface that faces towards the source/drain pattern, and
wherein, in a cross-sectional view of the semiconductor device, the upper surface of the bottom insulating spacer comprises a flat or concave shape.

9. The semiconductor device of claim 1, wherein the bottom insulating spacer comprises a first sub-bottom insulating spacer and a second sub-bottom insulating spacer,
wherein the second sub-bottom insulating spacer is between the first sub-bottom insulating spacer and the source/drain pattern, and
wherein the second sub-bottom insulating spacer comprises the first insulating material.

10. The semiconductor device of claim 9, wherein the first sub-bottom insulating spacer comprises a semiconductor material, and
at least a portion of the second surface of the lower insulating pattern does not overlap with the first sub-bottom insulating spacer in the first direction.

11. A semiconductor device comprising:
a lower insulating pattern comprising:
an upper plate portion;
a lower plate portion spaced apart from the upper plate portion in a first direction; and
a sidewall portion connecting the upper plate portion to the lower plate portion;
a first sheet pattern on the lower insulating pattern, the first sheet pattern being in contact with the upper plate portion of the lower insulating pattern;
a second sheet pattern on the first sheet pattern, spaced apart from the first sheet pattern in the first direction;
a gate structure comprising an inner gate structure between the first sheet pattern and the second sheet pattern, the inner gate structure extending in a second direction crossing the first direction, and the inner gate structure comprising a gate electrode and a gate insulating film;
an inner spacer between the first sheet pattern and the second sheet pattern;
a source/drain pattern connected to the first sheet pattern and the second sheet pattern; and
a bottom insulating spacer below the source/drain pattern in the first direction, the bottom insulating spacer overlapped with the source/drain pattern in the first direction, and in contact with the lower insulating pattern.

12. The semiconductor device of claim 11, wherein the lower insulating pattern further comprises a first surface and a second surface that are opposite to each other in the first direction,
wherein the upper plate portion of the lower insulating pattern comprises the first surface of the lower insulating pattern,
wherein the lower plate portion of the lower insulating pattern comprises the second surface of the lower insulating pattern, and
wherein a distance from the second surface of the lower insulating pattern to a contact uppermost portion of the bottom insulating spacer is smaller than or equal to a distance from the second surface of the lower insulating pattern to the first surface of the lower insulating pattern, the contact uppermost portion being a point of the bottom insulating spacer that is closest to a sidewall of the lower insulating pattern in a third direction that crosses the first direction and the second direction.

13. The semiconductor device of claim 11, wherein an insulating material of the inner spacer is the same as an insulating material of the lower insulating pattern, and the lower insulating pattern comprises an insulating material that is different from the insulating material of the bottom insulating spacer.

14. The semiconductor device of claim 13, wherein a dielectric constant of the insulating material of the lower insulating pattern is smaller than a dielectric constant of the insulating material of the bottom insulating spacer.

15. The semiconductor device of claim 11, wherein a thickness of the inner gate structure in the first direction is smaller than a thickness of the lower insulating pattern in the first direction.

16. The semiconductor device of claim 11, wherein the bottom insulating spacer comprises a first sub-bottom insulating spacer and a second sub-bottom insulating spacer,
wherein the second sub-bottom insulating spacer is between the first sub-bottom insulating spacer and the source/drain pattern,
wherein the first sub-bottom insulating spacer comprises a semiconductor material, and
wherein the second sub-bottom insulating spacer comprises an insulating material.

17. A semiconductor device comprising:
a lower insulating pattern comprising:
an air gap;
a first surface; and
a second surface opposite to the first surface in a first direction;
a first sheet pattern in contact with the first surface of the lower insulating pattern;
a second sheet pattern on the first sheet pattern, spaced apart from the first sheet pattern in the first direction;
a gate structure comprising an inner gate structure, the inner gate structure being between the first sheet pattern and the second sheet pattern, and extending in a second direction that crosses the first direction, and the inner gate structure comprising a gate electrode and a gate insulating film;
an inner spacer between the first sheet pattern and the second sheet pattern;
a first source/drain pattern connected to the first sheet pattern and the second sheet pattern;
a second source/drain pattern connected to the first sheet pattern and the second sheet pattern, and spaced apart from the first source/drain pattern in a third direction that crosses the first direction and the second direction;
a frontside wiring line on the first surface of the lower insulating pattern;
a backside wiring line on the second surface of the lower insulating pattern;
a first bottom insulating spacer below the first source/drain pattern in the first direction, and overlapped with the first source/drain pattern in the first direction;
a backside source/drain contact passing through the first bottom insulating spacer and connecting the first source/drain pattern to the backside wiring line; and
a frontside source/drain contact connecting the second source/drain pattern to the frontside wiring line.

18. The semiconductor device of claim 17, further comprising a second bottom insulating spacer between the second source/drain pattern and the backside wiring line,
wherein the second bottom insulating spacer overlaps with the second source/drain pattern in the first direction.

19. The semiconductor device of claim 17, wherein the second source/drain pattern is not connected to the backside wiring line, and no insulating spacer is between the second source/drain pattern and the backside wiring line.

20. The semiconductor device of claim 17, wherein the lower insulating pattern further comprises a sidewall connecting the first surface of the lower insulating pattern to the second surface of the lower insulating pattern, and
wherein at least a portion of the sidewall of the lower insulating pattern is in contact with the first bottom insulating spacer.
